(19) United States
(12) Patent Application Publication
(10) Pub. No.: US 2024/0004296 A1
(43) Pub. Date: Jan. 4, 2024

(54) RESIST UNDERLAYER FILM-FORMING COMPOSITION

(71) Applicant: NISSAN CHEMICAL CORPORATION, Tokyo (JP)

(72) Inventors: Hikaru TOKUNAGA, Toyama-shi (JP); Hirokazu NISHIMAKI, Toyama-shi (JP); Makoto NAKAJIMA, Toyama-shi (JP)

(73) Assignee: NISSAN CHEMICAL CORPORATION, Tokyo (JP)

(21) Appl. No.: 18/037,151

(22) PCT Filed: Nov. 16, 2021
(86) PCT No.: PCT/JP2021/042066

§ 371 Date: May 16, 2023

(30) Foreign Application Priority Data
Nov. 19, 2020 (JP) 2020-192504

(51) Int. Cl. G03F 7/11; G03F 7/20; H01L 21/027; C08G 65/40

(52) U.S. Cl. CPC G03F 7/11; G03F 7/20; H01L 21/0274; C08G 65/4012; C08G 2650/40; C08G 2650/20

(57) ABSTRACT

A resist underlayer film-forming composition: in which self-curing is performed at a low temperature without an acid catalyst or a crosslinking agent, the amount of a sublimate can be reduced, and a high-hardness film having high bending resistance; suitable as a crosslinking agent; exhibits higher flattening and heat resistance when used as a crosslinking agent; has embedding properties equivalent to conventional products; and has an optical constant or etching resistance freely changeable according to monomer selection. The composition contains a solvent and a polymer (X) containing a repeating structural unit which is obtained by alternately bonding, via a linking group —O—, an aromatic compound A having an ROCH₂— group (R is a monovalent organic group, a hydrogen atom, or a mixture thereof) to an aromatic compound B having at most 120 carbon atoms and different from A, and in which one to six B's are bonded to one A.

### TECHNICAL FIELD

The present invention relates to a resist underlayer film-forming composition, a resist underlayer film that is a baked product of a coating film of the composition, and a process for manufacturing a semiconductor device using the composition.

### BACKGROUND ART

Lithographic microfabrication is performed in the manufacture of semiconductor devices. It has been known that the lithographic process encounters a problem in which when a resist layer on a substrate is exposed to an ultraviolet laser beam, such as KrF excimer laser beam or ArF excimer laser beam, the resist is not patterned with the desired shape due to the influence of a standing wave generated by the reflection of the ultraviolet laser beam on the substrate surface. To solve this problem, a resist underlayer film (an antireflection film) has been provided between the substrate and the resist layer. It has been known that a novolak resin is used as a composition for forming such a resist underlayer film.

Moreover, the miniaturization of resist patterns has required thinner resist layers. A lithographic process is known in which at least two resist underlayer films are formed, and the resist underlayer films are used as mask materials. Some exemplary materials for forming the at least two layers are organic resins (for example, acrylic resins and novolak resins), silicon resins (for example, organopolysiloxanes), and inorganic silicon compounds (for example, SiON and SiO₂). A pattern is formed from the organic resin layers and is then used as a mask in dry etching. Here, the pattern is required to have an etching resistance to the etching gas (for example, fluorocarbon).

Compositions for forming such resist underlayer films are disclosed. For example, Patent Literature 1 discloses a resist underlayer film-forming composition that contains a solvent and a polymer having a structural unit represented by the following formula (1):

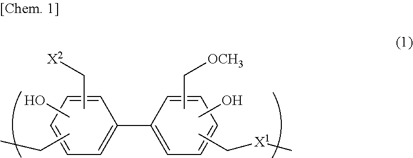

(in the formula, X¹ denotes a C₆-C₂₀ divalent organic group having at least one aromatic ring optionally substituted with a halogeno group, a nitro group, an amino group, or a hydroxy group; and X² denotes a C₆-C₂₀ organic group having at least one aromatic ring optionally substituted with a halogeno group, a nitro group, an amino group, or a hydroxy group, or denotes a methoxy group).

### CITATION LIST

### Patent Literature

Patent Literature 1: WO 2014/171326 A1

### SUMMARY OF INVENTION

### Technical Problem

Unfortunately, the conventional resist underlayer film-forming compositions are unsatisfactory in that they cannot be self-cured at a low temperature without containing an acid catalyst or a crosslinking agent, generate sublimates that contaminate apparatuses, and are incapable of forming a high-hardness film exhibiting a high bend resistance. Thus, there has been a demand that the drawbacks mentioned above be improved while maintaining such properties as insolubility with resist solvents, desirable optical constants and etching resistance.

### Solution to Problem

The present invention solves the problems mentioned above. Specifically, the present invention embraces the following.

[1] A resist underlayer film-forming composition comprising:
a solvent, and
a polymer (X) comprising a repeating structural unit, in which an aromatic compound A having an ROCH₂— group (R is a monovalent organic group, a hydrogen atom, or a mixture thereof) and a C₁₂₀ or lower aromatic compound B different from the compound A are alternately bonded to each other via a linking group —O—, the repeating structural units being such that 1 to 6 molecules of the compound B are bonded to one molecule of the compound A.
   [2] The resist underlayer film-forming composition according to [1], wherein the polymer (X) comprises a repeating structural unit represented by the formula (1):

[Chem. 2]

A₁-O—B₁—O Formula (1)

(in the formula (1), A₁ denotes an organic group derived from the aromatic compound A having an ROCH₂— group (R is a monovalent organic group, a hydrogen atom, or a mixture thereof) and 131 denotes an organic group different from A₁ and derived from the C₁₂₀ or lower aromatic compound B).
[3] The resist underlayer film-forming composition according to [2], wherein R in the formula (1) is a saturated or unsaturated, linear or branched, and C₂-C₂₀ aliphatic or C₃-C₂₀ alicyclic hydrocarbon group optionally substituted with a phenyl group, a naphthyl group, or an anthracenyl group and optionally interrupted by an oxygen atom, a nitrogen atom, or a carbonyl group; a hydrogen atom; or a mixture thereof.
[4] The resist underlayer film-forming composition according to [2], wherein B₁ in the formula (1) is represented by the following formula 2:

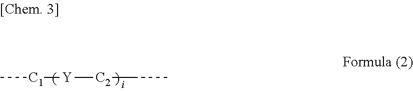

(in the formula (2),
C₁ and C₂ each independently denote a C₆-C₄₈ aromatic ring having 6 to 48 carbon atoms and optionally containing a heteroatom, or a hydrocarbon group containing a C₆-C₄₈ aromatic ring optionally containing a heteroatom,
Y denotes a single bond, a carbonyl group, a sulfonyl group, a —CR¹₂— group, or a —(CF₃)C(CF₃)— group,
R¹ denotes a C₁-C₁₀ alkyl group optionally interrupted by an oxygen atom, a carbonyl group, a nitrogen atom, a carbon-carbon double bond, or a carbon-carbon triple bond, and optionally having a carbon-carbon double bond or a carbon-carbon triple bond at a terminal; a hydroxy group; a hydrogen atom; a halogen; a C₆-C₂₀ aromatic hydrocarbon group; or —NR²₂,
R² denotes a C₁-C₁₀ chain or cyclic alkyl group optionally interrupted by a carbon-carbon double bond or a carbon-carbon triple bond, and optionally having a carbon-carbon double bond or a carbon-carbon triple bond at a terminal,
i is 0 or 1, and
the dotted lines each denote a bond with the oxygen atom).
   [5] The resist underlayer film-forming composition according to [4], wherein i in the formula (2) is 1.
   [6] The resist underlayer film-forming composition according to [4] or [5], wherein the polymer (X) further comprises a repeating structural unit represented by the formula (3):

[Chem. 4]

A₂-O—B₁—O Formula (3)

(in the formula (3), B₁ is represented by the formula 2, and A₂ denotes an organic group different from B₁ and derived from a C₁₂₀ or lower aromatic compound A′).
[7] The resist underlayer film-forming composition according to any one of [2] to [6], wherein A₁ in the formula (1) has no phenolic hydroxy group.
[8] The resist underlayer film-forming composition according to any one of [1] to [6], wherein the polymer (X) has an optionally substituted C₆-C₃₀ aromatic hydrocarbon group at least one end thereof.
[9] The resist underlayer film-forming composition according to any one of [1] to [8], further comprising a film material (Z) capable of undergoing a crosslinking reaction with the polymer (X).
[10] The resist underlayer film-forming composition according to any one of [1] to [9], further comprising a crosslinking agent.
[11] The resist underlayer film-forming composition according to any one of [1] to [10], further comprising an acid and/or an acid generator.
[12] The resist underlayer film-forming composition according to any one of [1] to [11], further comprising a surfactant.
[13] The resist underlayer film-forming composition according to any one of [1] to [12], wherein the solvent comprises a solvent having a boiling point of 160° C. or above.
[14] A resist underlayer film, which is a baked product of a coating film of the composition according to any one of [1] to [13].
[15] A process for manufacturing a semiconductor device, comprising the steps of:
forming a resist underlayer film using the composition according to any one of [1] to [13] on a semiconductor substrate;
forming a resist film on the resist underlayer film;
forming a resist pattern by applying a light or electron beam to the resist film followed by development;
forming a pattern in the resist underlayer film by etching the resist underlayer film through the formed resist pattern; and
processing the semiconductor substrate through the pattern in the resist underlayer film.
   [16] A process for manufacturing a semiconductor device, comprising the steps of:
forming a resist underlayer film using the composition according to any one of claims 1 to 13 on a semiconductor substrate;
forming a hard mask on the resist underlayer film;
forming a resist film on the hard mask;
applying a light or electron beam to the resist film followed by development to form a resist pattern;
etching the hard mask through the formed resist pattern to form a patterned hard mask; and
etching the resist underlayer film through the patterned hard mask to form a patterned resist underlayer film; and
processing the semiconductor substrate through the patterned resist underlayer film.
   [17] The process for manufacturing a semiconductor device according to or [16], wherein the step of forming a resist underlayer film is performed by a nanoimprinting method.

### Advantageous Effects of Invention

The present invention provides a novel resist underlayer film-forming composition that meets the demands, specifically, of being self-cured at a low temperature even without containing an acid catalyst or a crosslinking agent, generating reduced amounts of sublimates, and enabling forming a high-hardness film exhibiting a high bend resistance. The composition is also usable as a crosslinking agent. When used as a crosslinking agent, the composition offers a higher level of flatness and heat resistance than the conventional crosslinking agents. Moreover, the composition compares equally to the conventional products in gap-filling property, and can be freely controlled in optical constants and etching resistance through the selection of monomers.

### DESCRIPTION OF EMBODIMENTS

A resist underlayer film-forming composition according to the present invention contains a solvent, and a polymer (X) that contain a repeating structural unit, in which an aromatic compound A having an ROCH₂— group (R is a monovalent organic group, a hydrogen atom, or a mixture thereof) and a C₁₂₀ or lower aromatic compound B different from the compound A are alternately bonded to each other via a linking group —O—, the repeating structural unit being such that 1 to 6 molecules of the compound B are bonded to one molecule of the compound A.

[Polymers (X)]

The polymer (X) contains a repeating structural unit, in which an aromatic compound A having an ROCH₂— group (R is a monovalent organic group, a hydrogen atom, or a mixture thereof) and a C₁₂₀ or lower aromatic compound B different from the compound A are alternately bonded to each other via a linking group —O—. The repeating structural unit is such that 1 to 6 molecules, preferably 1 to 4 molecules, preferably 2 to 4 molecules, more preferably 2 to 3 molecules, and most preferably 2 molecules of the compound B are bonded to one molecule of the compound A.

Preferably, the polymer (X) contains a repeating structural unit represented by the formula (1):

[Chem. 5]

A₁-O—B₁—O Formula (1)

(in the formula (1), A₁ denotes an organic group derived from the aromatic compound A having an ROCH₂— group (R is a monovalent organic group, a hydrogen atom, or a mixture thereof) and B₁ denotes an organic group different from A₁ and derived from the C₁₂₀ or lower aromatic compound B).

Preferably, the polymer (X) further contains a repeating structural unit represented by the formula (3):

[Chem. 6]

A₂-O—B₁—O Formula (3)

(in the formula (3), B₁ is represented by the formula 2, and A₂ denotes an organic group different from B₁ and derived from a C₁₂₀ or lower aromatic compound A′).

The monovalent organic group R is preferably a saturated or unsaturated, linear or branched, and C₂-C₂₀ aliphatic or C₃-C₂₀ alicyclic hydrocarbon group optionally substituted with a phenyl group, a naphthyl group, or an anthracenyl group and optionally interrupted by an oxygen atom, a nitrogen atom, or a carbonyl group; a hydrogen atom; or a mixture thereof. The term “mixture” means that a plurality of ROCH₂— groups present in a single structural unit may be different from one another, and it also means that ROCH₂— groups in two or more structural units may be different from one another.

The saturated aliphatic hydrocarbon group is typically a linear or branched C₂-C₂₀ alkyl group, with examples including ethyl group, n-propyl group, i-propyl group, n-butyl group, i-butyl group, s-butyl group, t-butyl group, n-pentyl group, 1-methyl-n-butyl group, 2-methyl-n-butyl group, 3-methyl-n-butyl group, 1,1-dimethyl-n-propyl group, 1,2-dimethyl-n-propyl group, 2,2-dimethyl-n-propyl group, 1-ethyl-n-propyl group, n-hexyl, 1-methyl-n-pentyl group, 2-methyl-n-pentyl group, 3-methyl-n-pentyl group, 4-methyl-n-pentyl group, 1,1-dimethyl-n-butyl group, 1,2-dimethyl-n-butyl group, 1,3-dimethyl-n-butyl group, 2,2-dimethyl-n-butyl group, 2,3-dimethyl-n-butyl group, 3,3-dimethyl-n-butyl group, 1-ethyl-n-butyl group, 2-ethyl-n-butyl group, 1,1,2-trimethyl-n-propyl group, 1,2,2-trimethyl-n-propyl group, 1-ethyl-1-methyl-n-propyl group, 1-ethyl-2-methyl-n-propyl group, and 1-methoxy-2-propyl group.

Moreover, the group may be a cycloalkyl group. Examples of the C₃-C₂₀ cycloalkyl groups include cyclopropyl group, cyclobutyl group, 1-methyl-cyclopropyl group, 2-methyl-cyclopropyl group, cyclopentyl group, 1-methyl-cyclobutyl group, 2-methyl-cyclobutyl group, 3-methyl-cyclobutyl group, 1,2-dimethyl-cyclopropyl group, 2,3-dimethyl-cyclopropyl group, 1-ethyl-cyclopropyl group, 2-ethyl-cyclopropyl group, cyclohexyl group, 1-methyl-cyclopentyl group, 2-methyl-cyclopentyl group, 3-methyl-cyclopentyl group, 1-ethyl-cyclobutyl group, 2-ethyl-cyclobutyl group, 3-ethyl-cyclobutyl group, 1,2-dimethyl-cyclobutyl group, 1,3-dimethyl-cyclobutyl group, 2,2-dimethyl-cyclobutyl group, 2,3-dimethyl-cyclobutyl group, 2,4-dimethyl-cyclobutyl group, 3,3-dimethyl-cyclobutyl group, 1-n-propyl-cyclopropyl group, 2-n-propyl-cyclopropyl group, 1-i-propyl-cyclopropyl group, 2-i-propyl-cyclopropyl group, 1,2,2-trimethyl-cyclopropyl group, 1,2,3-trimethyl-cyclopropyl group, 2,2,3-trimethyl-cyclopropyl group, 1-ethyl-2-methyl-cyclopropyl group, 2-ethyl-1-methyl-cyclopropyl group, 2-ethyl-2-methyl-cyclopropyl group, and 2-ethyl-3-methyl-cyclopropyl group.

The unsaturated aliphatic hydrocarbon group is typically a C₂-C₂₀ alkenyl group, with examples including ethenyl group, 1-propenyl group, 2-propenyl group, 1-methyl-1-ethenyl group, 1-butenyl group, 2-butenyl group, 3-butenyl group, 2-methyl-1-propenyl group, 2-methyl-2-propenyl group, 1-ethylethenyl group, 1-methyl-1-propenyl group, 1-methyl-2-propenyl group, 1-pentenyl group, 2-pentenyl group, 3-pentenyl group, 4-pentenyl group, 1-n-propylethenyl group, 1-methyl-1-butenyl group, 1-methyl-2-butenyl group, 1-methyl-3-butenyl group, 2-ethyl-2-propenyl group, 2-methyl-1-butenyl group, 2-methyl-2-butenyl group, 2-methyl-3-butenyl group, 3-methyl-1-butenyl group, 3-methyl-2-butenyl group, 3-methyl-3-butenyl group, 1,1-dimethyl-2-propenyl group, 1-i-propylethenyl group, 1,2-dimethyl-1-propenyl group, 1,2-dimethyl-2-propenyl group, 1-cyclopentenyl group, 2-cyclopentenyl group, 3-cyclopentenyl group, 1-hexenyl group, 2-hexenyl group, 3-hexenyl group, 4-hexenyl group, 5-hexenyl group, 1-methyl-1-pentenyl group, 1-methyl-2-pentenyl group, 1-methyl-3-pentenyl group, 1-methyl-4-pentenyl group, 1-n-butylethenyl group, 2-methyl-1-pentenyl group, 2-methyl-2-pentenyl group, 2-methyl-3-pentenyl group, 2-methyl-4-pentenyl group, 2-n-propyl-2-propenyl group, 3-methyl-1-pentenyl group, 3-methyl-2-pentenyl group, 3-methyl-3-pentenyl group, 3-methyl-4-pentenyl group, 3-ethyl-3-butenyl group, 4-methyl-1-pentenyl group, 4-methyl-2-pentenyl group, 4-methyl-3-pentenyl group, 4-methyl-4-pentenyl group, 1,1-dimethyl-2-butenyl group, 1,1-dimethyl-3-butenyl group, 1,2-dimethyl-1-butenyl group, 1,2-dimethyl-2-butenyl group, 1,2-dimethyl-3-butenyl group, 1-methyl-2-ethyl-2-propenyl group, 1-s-butylethenyl group, 1,3-dimethyl-1-butenyl group, 1,3-dimethyl-2-butenyl group, 1,3-dimethyl-3-butenyl group, 1-i-butylethenyl group, 2,2-dimethyl-3-butenyl group, 2,3-dimethyl-1-butenyl group, 2,3-dimethyl-2-butenyl group, 2,3-dimethyl-3-butenyl group, 2-i-propyl-2-propenyl group, 3,3-dimethyl-1-butenyl group, 1-ethyl-1-butenyl group, 1-ethyl-2-butenyl group, 1-ethyl-3-butenyl group, 1-n-propyl-1-propenyl group, 1-n-propyl-2-propenyl group, 2-ethyl-1-butenyl group, 2-ethyl-2-butenyl group, 2-ethyl-3-butenyl group, 1,1,2-trimethyl-2-propenyl group, 1-t-butylethenyl group, 1-methyl-1-ethyl-2-propenyl group, 1-ethyl-2-methyl-1-propenyl group, 1-ethyl-2-methyl-2-propenyl group, 1-i-propyl-1-propenyl group, 1-i-propyl-2-propenyl group, 1-methyl-2-cyclopentenyl group, 1-methyl-3-cyclopentenyl group, 2-methyl-1-cyclopentenyl group, 2-methyl-2-cyclopentenyl group, 2-methyl-3-cyclopentenyl group, 2-methyl-4-cyclopentenyl group, 2-methyl-5-cyclopentenyl group, 2-methylene-cyclopentyl group, 3-methyl-1-cyclopentenyl group, 3-methyl-2-cyclopentenyl group, 3-methyl-3-cyclopentenyl group, 3-methyl-4-cyclopentenyl group, 3-methyl-5-cyclopentenyl group, 3-methylene-cyclopentyl group, 1-cyclohexenyl group, 2-cyclohexenyl group, and 3-cyclohexenyl group.

Preferably, R is —H, a —CH₃ group, a —CH₂CH₃ group, a —CH₂CH₂CH₃ group, a —CH₂CH₂CH₂CH₃ group, a cyclohexyl group, or a —CH(CH₃)CH₂OCH₃ group.

B₁ in the formula (1) is preferably represented by the following formula 2:

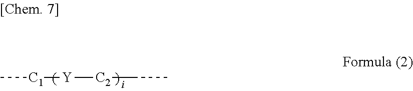

(In the formula (2),
C₁ and C₂ each independently denote a C₆-C₄₈ aromatic ring having 6 to 48 carbon atoms and optionally containing a heteroatom, or a hydrocarbon group containing a C₆-C₄₈ aromatic ring optionally containing a heteroatom,
Y denotes a single bond, a carbonyl group, a sulfonyl group, a —CR¹₂— group, or a —(CF₃)C(CF₃)— group,
R¹ denotes a C₁-C₁₀ alkyl group optionally interrupted by an oxygen atom, a carbonyl group, a nitrogen atom, a carbon-carbon double bond, or a carbon-carbon triple bond, and optionally having a carbon-carbon double bond or a carbon-carbon triple bond at a terminal; a hydroxy group; a hydrogen atom; a halogen; a C₆-C₂₀ aromatic hydrocarbon group; or —NR²₂,
R² denotes a C₁-C₁₀ chain or cyclic alkyl group optionally interrupted by a carbon-carbon double bond or a carbon-carbon triple bond, and optionally having a carbon-carbon double bond or a carbon-carbon triple bond at a terminal,
i is 0 or 1, and
the dotted line denotes a bond with the oxygen atom).

Preferably, C₁ and C₂ each independently have an electron-withdrawing substituent on the aromatic ring. Examples of the electron-withdrawing substituents include, although not particularly limited to, cyano group, ketone group, nitro group, aldehyde group, carboxy group, and ester group.

Preferably, i in the formula (2) is 1.

The polymer (X) may be synthesized by subjecting an aromatic compound A having an ROCH₂— group (R is a monovalent organic group, a hydrogen atom, or a mixture thereof), a C₁₂₀ or lower aromatic compound B different from the compound A, optionally a compound that contains a functional group serving as a linking group (for example, an aldehyde, a ketone, or ROCH₂—Ar—CH₂OR (R is a monovalent organic group, a hydrogen atom, or a mixture thereof)), and further optionally a C₁₂₀ or lower aromatic compound A′ different from the B₁, to polymerization reaction in the presence of a base catalyst (such as, for example, sodium hydroxide, potassium hydroxide, potassium carbonate, trimethylamine, or triethylamine).

The aromatic compound A having an ROCH₂— group (R is a monovalent organic group, a hydrogen atom, or a mixture thereof) that is used in the synthesis of the polymer (X) is preferably a C₁₂₀ or lower aromatic compound.

The aromatic compound A, provided that it has an ROCH₂— group, may be:
(a) a monocyclic compound, such as benzene,
(b) a condensed ring compound, such as naphthalene, anthracene, or pyrene,
(c) a heterocyclic compound, such as furan, pyrrole, thiophene, pyridine, carbazole, iminostilbene, phenothiazine, indole, or indolocarbazole,
(d) a compound composed of any of the compounds (a) to (c) linked together via a single bond or an alkylene group between their aromatic rings, such as biphenyl, phenylindole, α,α,α′,α′-tetrakis(4-hydroxyphenyl)-p-xylene, or calixarene,
(e) a compound composed of any of the compounds (a) to (d) linked together via a spacer, for example, —(CH₂)ₙ— (n=1 to 20), —CH═CH—, —C≡C—, —N≡N—, —NH—, —NR—, —NHCO—, —NRCO—, —S—, —COO—, —O—, —CO—, or —CH═N—, between their aromatic rings, such as 2,2-diphenylpropane, or
(f) a fluorene, such as 9,9-bis(4-hydroxyphenyl)fluorene, or a fluorene or fluorenone skeleton-containing compound described later.

The above examples are not limiting.

Examples of the aromatic compound A include the following compounds, provided that they have an ROCH₂— group: benzene, biphenyl, 2,2-diphenylpropane, thiophene, furan, pyridine, pyrimidine, pyrazine, pyrrole, oxazole, thiazole, imidazole, naphthalene, anthracene, quinoline, carbazole, quinazoline, purine, indolizine, benzothiophene, benzofuran, indole, phenylindole, acridine, and fluorene, although not limited thereto. More specific examples include 3,3′,5,5′-tetramethoxymethyl-4,4′-dihydroxybiphenyl, and 2,2-bis(4-hydroxy-3,5-dihydroxymethylphenyl)propane.

Examples of the aromatic compound A further includes fluorene or fluorenone skeleton-containing compounds illustrated below:

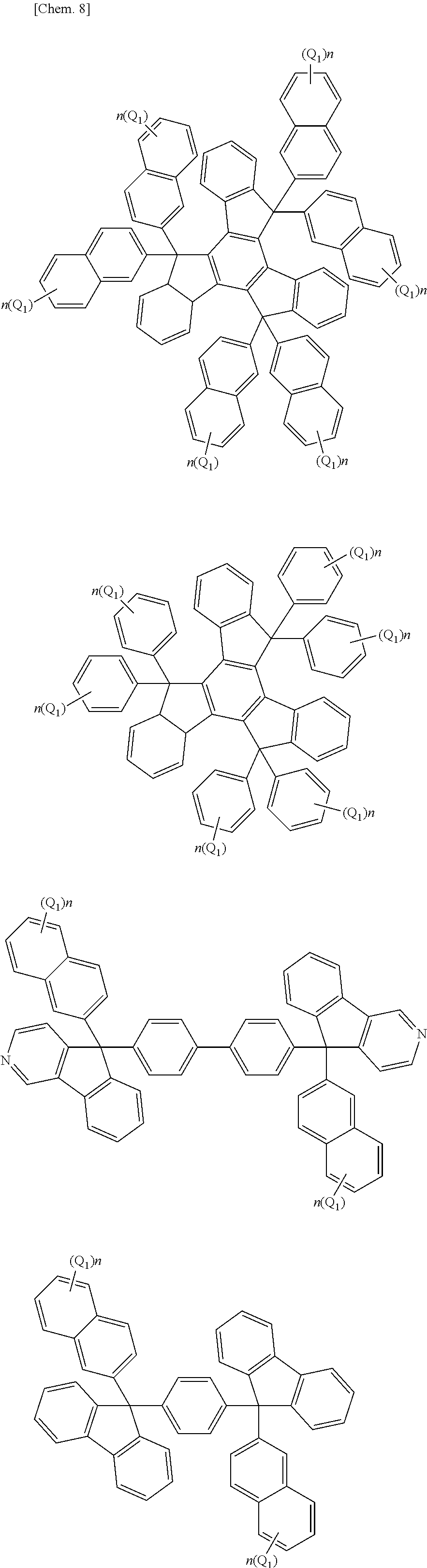

Q₁=—OH or —O CH₂CCH and two or more of Q₁ is —OH.
n independently is an integer of Q₁ that can substitute on the aromatic ring.

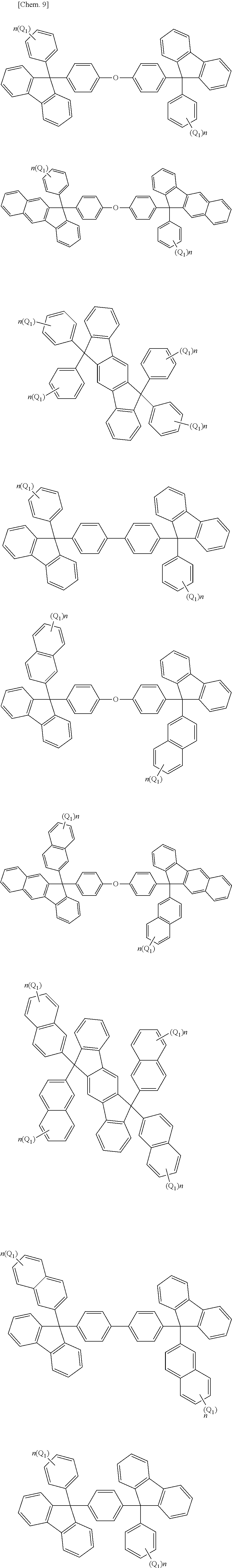

Q₁=—OH or —O CH₂CCH and two or more of Q₁ is —OH.
n independently is an integer of Q₁ that can substitute on the aromatic ring.

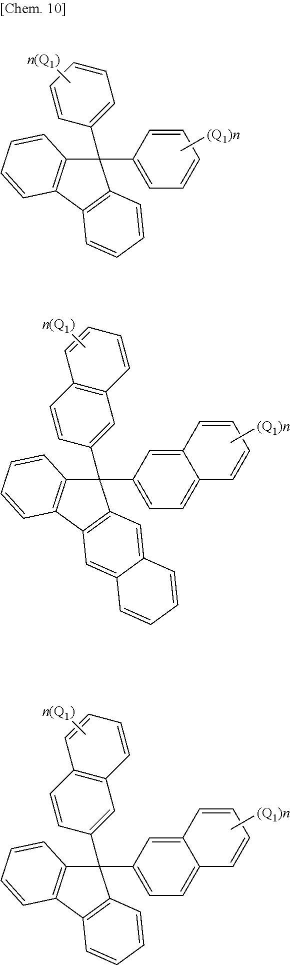

Q₁=—OH or —O CH₂CCH and two or more of Q₁ is —OH.
n independently is an integer of Q₁ that can substitute on the aromatic ring.

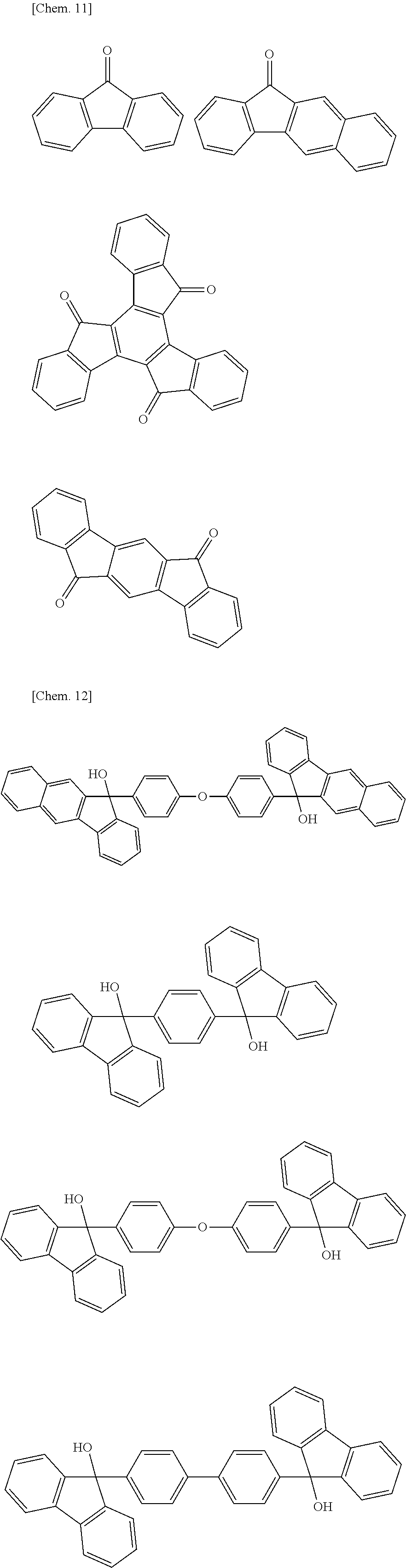

The aromatic compound A as a starting material for the polymer (X) may have a phenolic hydroxy group, but A₁ in the formula (1) preferably has no phenolic hydroxy group. Here, “has no phenolic hydroxy group” means that the amount of phenolic hydroxy groups is below the lower limit of detection when measured by an analytical technique, such as NMR, or it means that the amount detected is trace at most.

The aromatic compound B is a C₁₂₀ or lower aromatic compound that should be different from the aromatic compound A. The description for the aromatic compound is the same as that for the aromatic compound A. The aromatic compound B preferably has a halogen atom on the aromatic ring, and more preferably has two or more halogen atoms, and the halogen is preferably fluorine. Examples of the aromatic compounds B include, but are not limited to, 2,5-difluorotoluene, 2,5-difluoroaniline, 2,5-difluorophenol, 1,2,3-trifluorobenzene, 2,5-difluorobenzonitrile, 2,5-difluorobenzaldehyde, 2,5-difluorobenzylamine, 2,5-difluorobenzyl alcohol, 2,5-difluoroanisole, 2,3,6-trifluorophenol, 2,5-difluorobenzyl cyanide, 4-amino-2,5-difluorobenzonitrile, 2,5-difluorophenyl isocyanate, 2,5-difluoroacetophenone, 2,3,5-trifluorobenzonitrile, 2,4,5-trifluorobenzonitrile, 2,5-difluorobenzoic acid, 2,5-difluoronitrobenzene, 2,4,5-trifluorobenzyl alcohol, 2,5-difluorobenzyl chloride, 2,3,5,6-tetrafluorophenol, 1,2-difluorobenzene, 2,3-difluorotoluene, 3,4-difluorotoluene, 3,4-difluoroaniline, 2,3-difluoroaniline, 2,3-difluorophenol, 3,4-difluorophenol, 4-ethynyl-1,2-difluorobenzene, 3,4-difluorobenzonitrile, 2,3-difluorobenzonitrile, 2,3-difluorobenzaldehyde, 3,4-difluorobenzaldehyde, 2,3-difluorobenzylamine, 3,4-difluorobenzyl alcohol, 3,4-difluoroanisole, 2,3-difluoroanisole, 2,3-difluorobenzyl alcohol, 3,4-difluorothiol, 2,3,4-trifluorophenol, 2,3,6-trifluorophenol, 2,3-difluoroacetonitrile, 3,4-difluorophenyl isocyanate, 5-ethynyl-1,2,3-trifluorobenzene, 3,4-difluoroacetophenone, 2,3,4-trifluorobenzonitrile, 3,4,5-trifluorobenzonitrile, 2,3-difluorobenzoic acid, 3,4-difluorobenzoic acid, 3,4-difluoronitrobenzene, 4,5-difluoronilonitrile, 2,3,4-trifluorobenzaldehyde, 3,4,5-trifluorobenzaldehyde, 2,3,6-trifluorobenzaldehyde 1,3-difluorobenzene, 2,4-difluorotoluene, 2,6-difluorotoluene, 3,5-difluoroaniline, 2,6-difluoroaniline, 3,5-difluorophenol, 2,4-difluorophenol, 2,6-difluorophenol, 1,3,5-trifluorobenzaldehyde, 1-ethynyl-2,4-difluorobenzene, 1-ethynyl-3,5-difluorobenzene, 2,6-difluorobenzonitrile, 3,5-difluorobenzonitrile, 2,4-difluorobenzonitrile, 3,5-difluorobenzaldehyde, 2,6-difluorobenzaldehyde, 2,4-difluorobenzaldehyde, 1-ethyl-3,5-difluorobenzaldehyde, 3,5-difluorobenzylaniline, 2,6-difluorobenzylaniline, 2,4-difluorobenzyl alcohol, 2,4-difluoroanisole, 3,5-difluorobenzyl alcohol, 3,5-difluoroanisole, 2,6-difluorobenzyl alcohol, 2,6-difluoroanisole, 2,4-difluorothiol, 2,6-difluorobenzyl cyanide, 3,5-difluorobenzyl cyanide, 2,4-difluorobenzyl cyanide, 2,4-difluorophenyl isocyanate, 2,6-difluoro-4-hydroxybenzonitrile, 1,3-difluoro-5-propylbenzene, 2,4,6-trifluorobenzonitrile, 2,6-difluorobenzoic acid, 2,4-difluorobenzoic acid, 3,5-difluorobenzoic acid, 2,6-difluoronitrobenzene, 3,5-difluoronitrobenzene, 2,4,6-trifluorobenzaldehyde, 2,4,5-trifluorobenzyl alcohol, 2,6-difluorobenzyl chloride, 2,6-difluoronaphthalene, 3,6-difluoronaphthalene, 1,5-difluoronaphthalene, 2,7-difluoronaphthalene, 1,6-difluoronaphthalene, 1,2-difluoronaphthalene, 1,7-difluoronaphthalene, 1,3-difluoronaphthalene, 1,4-difluoronaphthalene, 2,2-difluorobiphenyl, 4,4-difluorobiphenyl, 9,9-bis(fluorophenyl)fluorene, bis(fluoronaphthyl)fluorene, 9,9-bis(4-fluorophenyl)fluorene, 1,4-difluorobenzene, 4,4′-difluorodiphenylmethane, and 4,4-difluorobenzophenone. And 1,4-difluorobenzene, 4,4′-difluorodiphenylmethane, and 4,4-difluorobenzophenone are preferable.

The aromatic compound A′ is a C₁₂₀ or lower aromatic compound that should be capable of giving an organic group different from B₁. The description for the aromatic compound is the same as that for the aromatic compound A. Examples of the aromatic compounds A′ include, but are not limited to, hydroquinone, resorcinol, catechol, phloroglucinol, 2,6-dihydroxynaphthalene, 3,6-dihydroxynaphthalene, 2,7-dihydroxynaphthalene, 1,6-dihydroxynaphthalene, 1,2-dihydroxynaphthalene, 1,7-dihydroxynaphthalene, 1,3-dihydroxynaphthalene, 1,4-dihydroxynaphthalene, 4,4-biphenol, 4,4′,4″-trihydroxytriphenylmethane, calixarene, bisphenol A, bisphenol AP, bisphenol AF, bisphenol B, bisphenol BP, bisphenol C, bisphenol E, bisphenol F, bisphenol G, bisphenol M, bisphenol S, bisphenol P, bisphenol PH, bisphenol TMC, bisphenol Z, dihydroxycarbazole, dihydroxyphenylamine, α,α,α′,α′-tetrakis(4-hydroxyphenyl)-p-xylene, 9,9-bis(hydroxyphenyl)fluorene, bis(hydroxynaphthyl)fluorene, 1,5-dihydroxynaphthalene, 2,2-biphenol, and 1,1,1-tris(4-hydroxyphenyl)ethane. And 9,9-bis(4-hydroxyphenyl)fluorene, 1,5-dihydroxynaphthalene, 2,2-biphenol, and 1,1,1-tris(4-hydroxyphenyl)ethane are preferable.

Each of the compounds used for the synthesis of the polymer (X) is not limited to a single compound and may be a combination of two or more compounds. Thus, the repeating structural units in which the aromatic compound A having an ROCH₂— group and the C₁₂₀ or lower aromatic compound B different from the compound A are alternately bonded to each other via a linking group —O— may be the same as or different from one another.

At least one end of the polymer (X) may have an optionally substituted C₆-C₃₀ aromatic hydrocarbon group. Examples of such an aromatic hydrocarbon group include phenyl group and naphthyl group each optionally substituted with a substituent, such as a vinyl group.

A feature of the present invention resides in that the repeating structural unit are constructed by alternate bonding of the aromatic compound A, the aromatic compound B, and optionally the aromatic compound A′, via a linking group —O—.

The weight average molecular weight of the polymer (X) contained in the resist underlayer film-forming composition of the present invention is not particularly limited. The weight average molecular weight is, for example, 500 or more, for example, 1,000 or more, or, for example, 2,000 or more, and is, for example, 500,000 or less, or, for example, 100,000 or less, relative to the standard polystyrene.

[Solvents] The resist underlayer film-forming composition of the present invention may be prepared by dissolving the components described hereinabove into an appropriate solvent, and is used as a uniform solution.

Examples of the solvents include ethylene glycol monomethyl ether, ethylene glycol monoethyl ether, diethylene glycol monomethyl ether, diethylene glycol monoethyl ether, propylene glycol, propylene glycol monomethyl ether, propylene glycol monopropyl ether, propylene glycol monomethyl ether acetate, propylene glycol propyl ether acetate, methyl cellosolve acetate, ethyl cellosolve acetate, methyl ethyl ketone, cyclopentanone, cyclohexanone, ethyl 2-hydroxypropionate, ethyl 2-hydroxy-2-methylpropionate, ethyl ethoxyacetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, and N-methylpyrrolidone.

Moreover, a high-boiling solvent having a boiling point of 180° C. or above may be used. Specific examples of the high-boiling organic solvents include 1-octanol, 2-ethylhexanol, 1-nonanol, 1-decanol, 1-undecanol, ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, tripropylene glycol, glycerin, n-nonyl acetate, ethylene glycol monohexyl ether, ethylene glycol mono-2-ethylhexyl ether, ethylene glycol monophenyl ether, ethylene glycol monobenzyl ether, diethylene glycol monoethyl ether, diethylene glycol monoisopropyl ether, diethylene glycol mono-n-butyl ether, diethylene glycol monoisobutyl ether, diethylene glycol monohexyl ether, diethylene glycol monophenyl ether, diethylene glycol monobenzyl ether, diethylene glycol diethyl ether, diethylene glycol dibutyl ether, diethylene glycol butyl methyl ether, triethylene glycol dimethyl ether, triethylene glycol monomethyl ether, triethylene glycol-n-butyl ether, triethylene glycol butyl methyl ether, triethylene glycol diacetate, tetraethylene glycol dimethyl ether, dipropylene glycol monomethyl ether, dipropylene glycol mono-n-propyl ether, dipropylene glycol mono-n-butyl ether, tripropylene glycol dimethyl ether, tripropylene glycol monomethyl ether, tripropylene glycol mono-n-propyl ether, tripropylene glycol mono-n-butyl ether, ethylene glycol monoethyl ether acetate, ethylene glycol monobutyl ether acetate, diethylene glycol monomethyl ether acetate, diethylene glycol monoethyl ether acetate, diethylene glycol monobutyl ether acetate, triacetin, propylene glycol diacetate, dipropylene glycol monomethyl ether acetate, dipropylene glycol methyl-n-propyl ether, dipropylene glycol methyl ether acetate, 1,4-butanediol diacetate, 1,3-butylene glycol diacetate, 1,6-hexanediol diacetate, triethylene glycol diacetate, γ-butyrolactone, dihexyl malonate, diethyl succinate, dipropyl succinate, dibutyl succinate, dihexyl succinate, dimethyl adipate, diethyl adipate, and dibutyl adipate.

The above solvents may be used each alone or in combination of two or more thereof. The proportion of the solid components that are residue after removal of the organic solvents from the composition ranges, for example, 0.5% by mass to 30% by mass, and preferably 0.8% by mass to 15% by mass.

Moreover, use may be made of the following compounds disclosed in WO 2018/131562 A1.

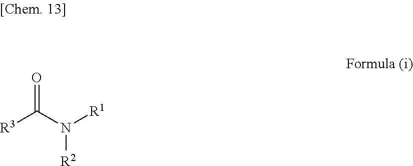

(In the formula (i), R¹, R², and R³ each denote a hydrogen atom or a C₁-C₂₀ alkyl group optionally interrupted by an oxygen atom, a sulfur atom, or an amide bond, and may be the same as or different from one another and may be bonded to one another to form a ring structure.)

Examples of the C₁-C₂₀ alkyl groups include optionally substituted, linear or branched alkyl groups, such as, for example, methyl group, ethyl group, n-propyl group, isopropyl group, n-butyl group, sec-butyl group, tert-butyl group, n-pentyl group, isopentyl group, neopentyl group, n-hexyl group, isohexyl group, n-heptyl group, n-octyl group, cyclohexyl group, 2-ethylhexyl group, n-nonyl group, isononyl group, p-tert-butylcyclohexyl group, n-decyl group, n-dodecylnonyl group, undecyl group, dodecyl group, tridecyl group, tetradecyl group, pentadecyl group, hexadecyl group, heptadecyl group, octadecyl group, nonadecyl group, and eicosyl group. C₁-C₁₂ alkyl groups are preferable, C₁-C₈ alkyl groups are more preferable, and C₁-C₄ alkyl groups are still more preferable.

Examples of the C₁-C₂₀ alkyl groups interrupted by an oxygen atom, a sulfur atom, or an amide bond include those containing a structural unit —CH₂—O—, —CH₂—S—, —CH₂—NHCO—, or —CH₂—CONH—. The alkyl groups may contain one, or two or more units represented by —O—, —S—, —NHCO—, or —CONH—. Specific examples of the C₁-C₂₀ alkyl groups interrupted by an —O—, —S—, —NHCO—, or —CONH— unit include methoxy group, ethoxy group, propoxy group, butoxy group, methylthio group, ethylthio group, propylthio group, butylthio group, methylcarbonylamino group, ethylcarbonylamino group, propylcarbonylamino group, butylcarbonylamino group, methylaminocarbonyl group, ethylaminocarbonyl group, propylaminocarbonyl group, and butylaminocarbonyl group, and further include methyl group, ethyl group, propyl group, butyl group, pentyl group, hexyl group, heptyl group, octyl group, nonyl group, decyl group, dodecyl group, and octadecyl group each substituted with a substituent, such as a methoxy group, an ethoxy group, a propoxy group, a butoxy group, a methylthio group, an ethylthio group, a propylthio group, a butylthio group, a methylcarbonylamino group, an ethylcarbonylamino group, a methylaminocarbonyl group, or an ethylaminocarbonyl group. Methoxy group, ethoxy group, methylthio group, and ethylthio group are preferable, and methoxy group and ethoxy group are more preferable.

The above solvents have relatively a high boiling point and are therefore effective for imparting a high gap-filling property and a high flattening property to the resist underlayer film-forming composition.

Specific examples of preferred compounds represented by the formula (i) are illustrated below:

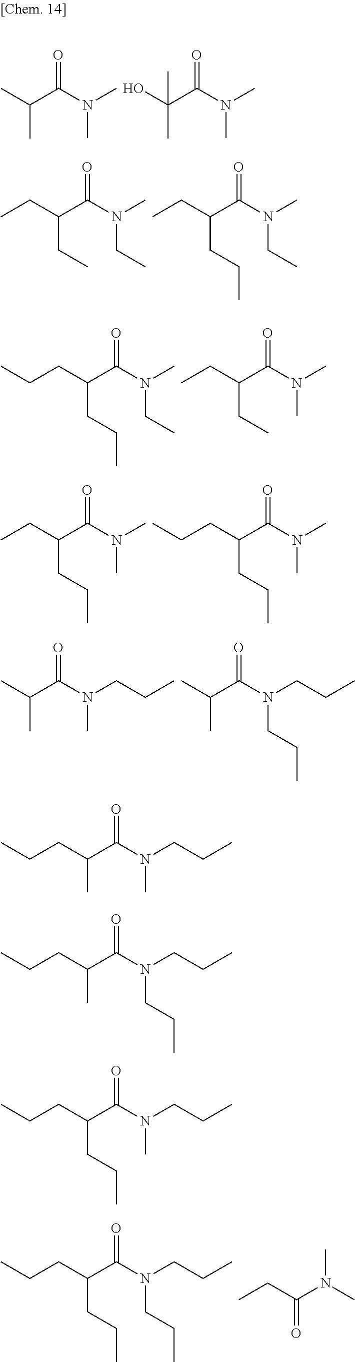

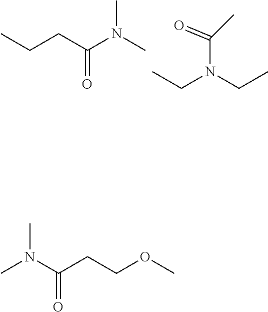

Of those illustrated above, preferred compounds are 3-methoxy-N,N-dimethylpropionamide, N,N-dimethylisobutyramide, and the compounds represented by the following formulas:

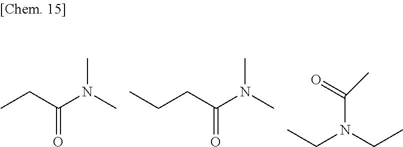

Particularly preferred compounds represented by the formula (i) are 3-methoxy-N,N-dimethylpropionamide and N,N-dimethylisobutyramide.

The above solvents may be used each alone or in combination of two or more thereof. Of the solvents above, those having a boiling point of 160° C. or above are preferable, and, for example, propylene glycol monomethyl ether, propylene glycol monomethyl ether acetate, ethyl lactate, butyl lactate, cyclohexanone, 3-methoxy-N,N-dimethylpropionamide, N,N-dimethylisobutyramide, 2,5-dimethylhexane-1,6-diyl diacetate (DAH; CAS: 89182-68-3), and 1,6-diacetoxyhexane (CAS: 6222-17-9) are preferable. Propylene glycol monomethyl ether, propylene glycol monomethyl ether acetate, and N,N-dimethylisobutyramide are particularly preferable.

[Optional Components]

As an optional component, the resist underlayer film-forming composition of the present invention may further contain at least one of a crosslinking agent, an acid and/or an acid generator, a thermal acid generator, and a surfactant.

(Crosslinking Agent)

The resist underlayer film-forming composition of the present invention may further contain a crosslinking agent. The crosslinking agent used here is preferably a crosslinking compound that has at least two crosslink-forming substituents. Examples include melamine compounds, substituted urea compounds, and phenolic compounds, each of which have a crosslink-forming substituent, such as methylol group or methoxymethyl group, and further include polymers of these compounds. Specific examples of such compounds include methoxymethylated glycolurils, butoxymethylated glycolurils, methoxymethylated melamines, butoxymethylated melamines, methoxymethylated benzoguanamines, and butoxymethylated benzoguanamines, such as, for example, tetramethoxymethyl glycoluril, tetrabutoxymethyl glycoluril, and hexamethoxymethylmelamine. Moreover, examples of the substituted urea compounds include such compounds as methoxymethylated ureas, butoxymethylated ureas, and methoxymethylated thioureas, such as, for example, tetramethoxymethylurea and tetrabutoxymethylurea. Moreover, condensates of these compounds may also be used. Examples of the phenolic compounds include tetrahydroxymethylbiphenol, tetramethoxymethylbiphenol, tetrahydroxymethylbisphenol, tetramethoxymethylbisphenol, and the compounds represented by the following formulas:

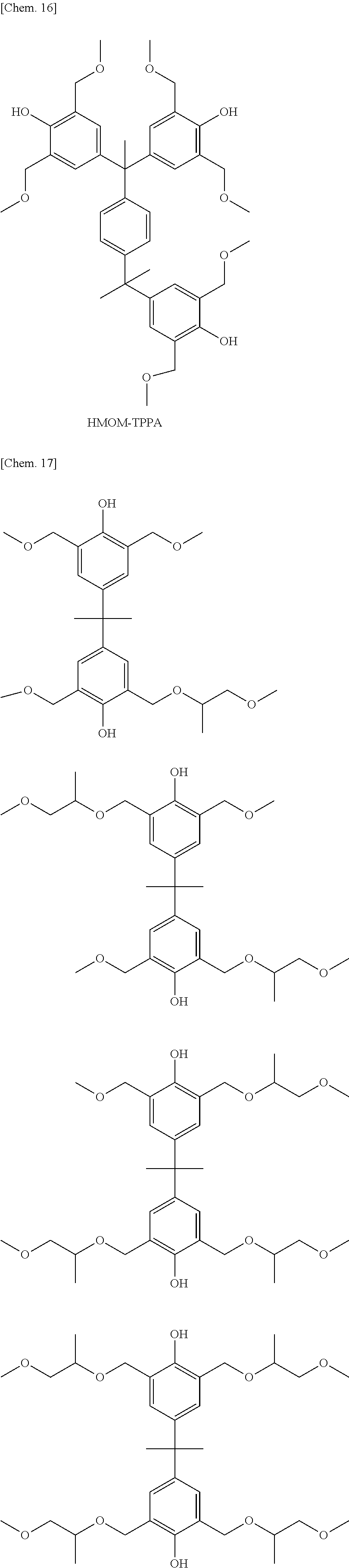

Moreover, a compound having at least two epoxy groups may also be used as the crosslinking agent. Examples of such compounds include tris(2,3-epoxypropyl) isocyanurate, 1,4-butanediol diglycidyl ether, 1,2-epoxy-4-(epoxyethyl)cyclohexane, glycerol triglycidyl ether, diethylene glycol diglycidyl ether, 2,6-diglycidylphenyl glycidyl ether, 1,1,3-tris[p-(2,3-epoxypropoxy)phenyl] propane, 1,2-cyclohexanedicarboxylic acid diglycidyl ester, 4,4′-methylenebis(N,N-diglycidylaniline), 3,4-epoxycyclohexylmethyl-3,4-epoxycyclohexane carboxylate, trimethylolethane triglycidyl ether, bisphenol-A-diglycidyl ether; EPOLEAD [registered trademark] series GT-401, GT-403, GT-301, and GT-302, and CELLOXIDE [registered trademark] series 2021 and 3000, all manufactured by Daicel Corporation; 1001, 1002, 1003, 1004, 1007, 1009, 1010, 828, 807, 152, 154, 180S75, 871, and 872, all manufactured by Mitsubishi Chemical Corporation; EPPN series 201 and 202, and EOCN series 102, 103S, 104S, 1020, 1025, and 1027, all manufactured by Nippon Kayaku Co., Ltd.; Denacol [registered trademark] series EX-252, EX-611, EX-612, EX-614, EX-622, EX-411, EX-512, EX-522, EX-421, EX-313, EX-314, and EX-321, all manufactured by Nagase ChemteX Corporation; CY175, CY177, CY179, CY182, CY184, and CY192, all manufactured by BASF Japan; and EPICRON series 200, 400, 7015, 835LV, and 850CRP, all manufactured by DIC CORPORATION. As the compound having at least two epoxy groups, epoxy resins having an amino group may also be used. Examples of such epoxy resins include YH-434 and YH-434L (manufactured by NIPPON STEEL Epoxy Manufacturing Co., Ltd.).

Moreover, as the crosslinking agent, a compound having at least two blocked isocyanate groups may also be used. Examples of such compounds include TAKENATE [registered trademark] series B-830 and B-870N manufactured by Mitsui Chemicals, Inc.; and VESTANAT [registered trademark] B1358/100 manufactured by Evonik Degussa.

Moreover, as the crosslinking agent, a compound having at least two vinyl ether groups may also be used. Examples of such compounds include bis(4-(vinyloxymethyl)cyclohexylmethyl) glutarate, tri(ethylene glycol) divinyl ether, divinyl adipate ester, diethylene glycol divinyl ether, 1,2,4-tris(4-vinyloxybutyl) trimellitate, 1,3,5-tris(4-vinyloxybutyl) trimellitate, bis(4-(vinyloxy)butyl) terephthalate, bis(4-(vinyloxy)butyl) isophthalate, ethylene glycol divinyl ether, 1,4-butanediol divinyl ether, tetramethylene glycol divinyl ether, tetraethylene glycol divinyl ether, neopentyl glycol divinyl ether, trimethylolpropane trivinyl ether, trimethylolethane trivinyl ether, hexanediol divinyl ether, 1,4-cyclohexanediol divinyl ether, tetraethylene glycol divinyl ether, pentaerythritol divinyl ether, pentaerythritol trivinyl ether, and cyclohexanedimethanol divinyl ether.

Moreover, as the crosslinking agent, a crosslinking agent having high heat resistance may also be used. The crosslinking agent having high heat resistance may be preferably a compound that contains in the molecule a crosslink-forming substituent having an aromatic ring (for example, a benzene ring or a naphthalene ring).

Examples of such compounds include compounds having a partial structure of the following formula (4), and polymers and oligomers having a repeating unit of the following formula (5):

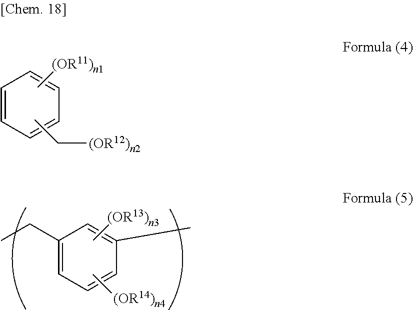

R¹¹, R¹², R¹³ and R¹⁴ are each a hydrogen atom or a C₁-C₁₀ alkyl group. Examples of the alkyl groups are the same as exemplified above.

Examples of the compounds, the polymers, and the oligomers having the formula (4) or the formula (5) are illustrated below:

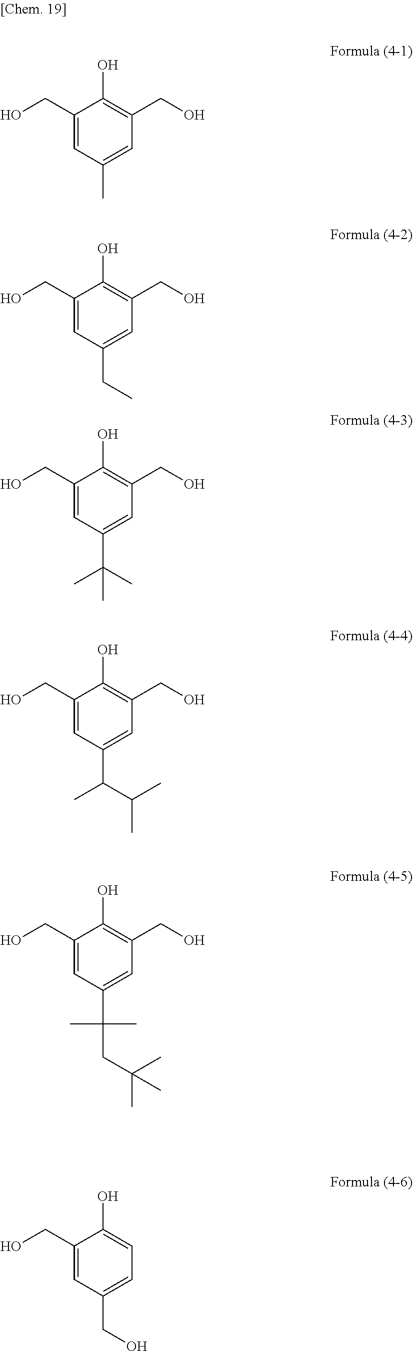

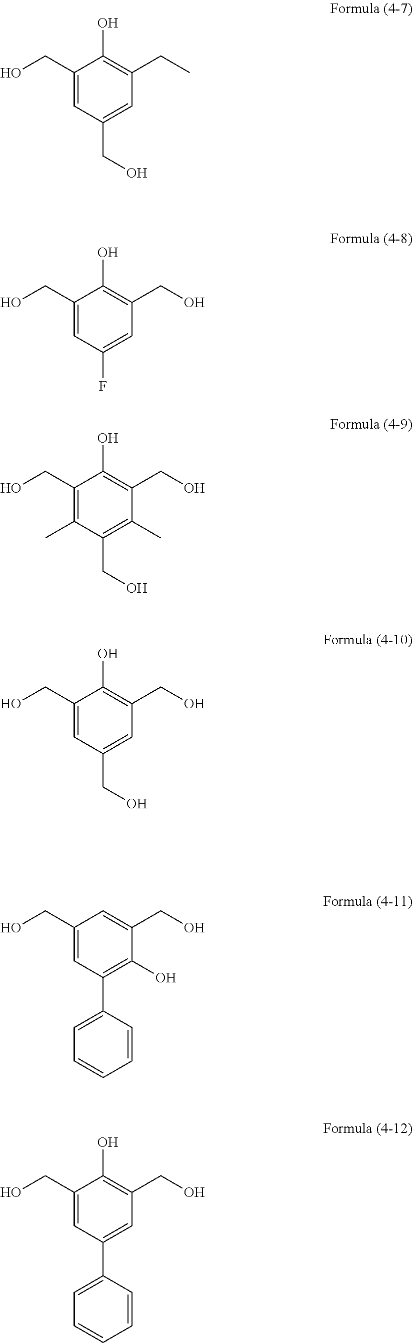 [SMILES: CCc1cc(CO)cc(CO)c1O ; OCc1cc(F)cc(CO)c1O ; Cc1c(CO)c(C)c(CO)c(O)c1CO ; OCc1cc(CO)c(O)c(CO)c1 ; OCc1cc(CO)c(O)c(-c2ccccc2)c1 ; OCc1cc(-c2ccccc2)cc(CO)c1O]

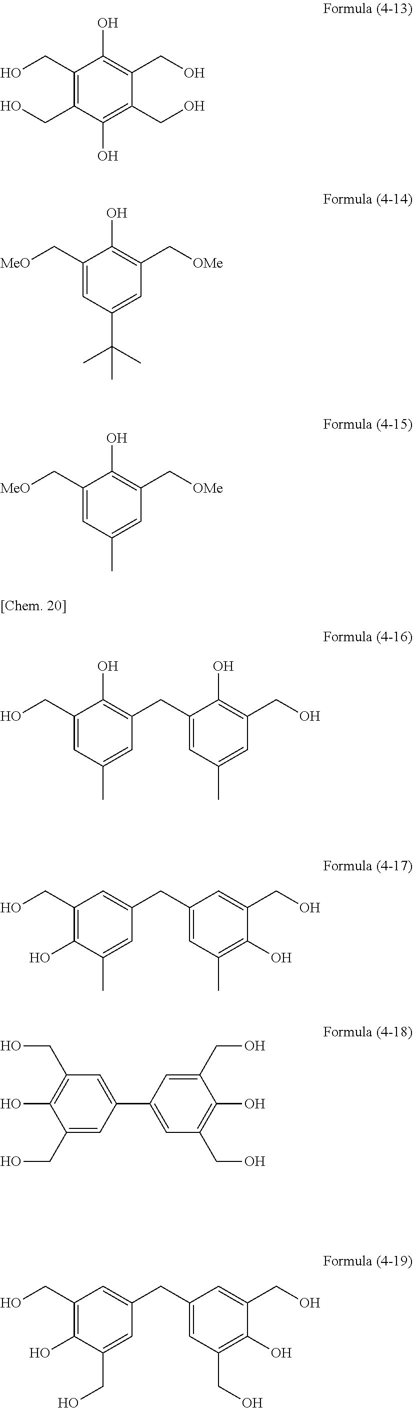

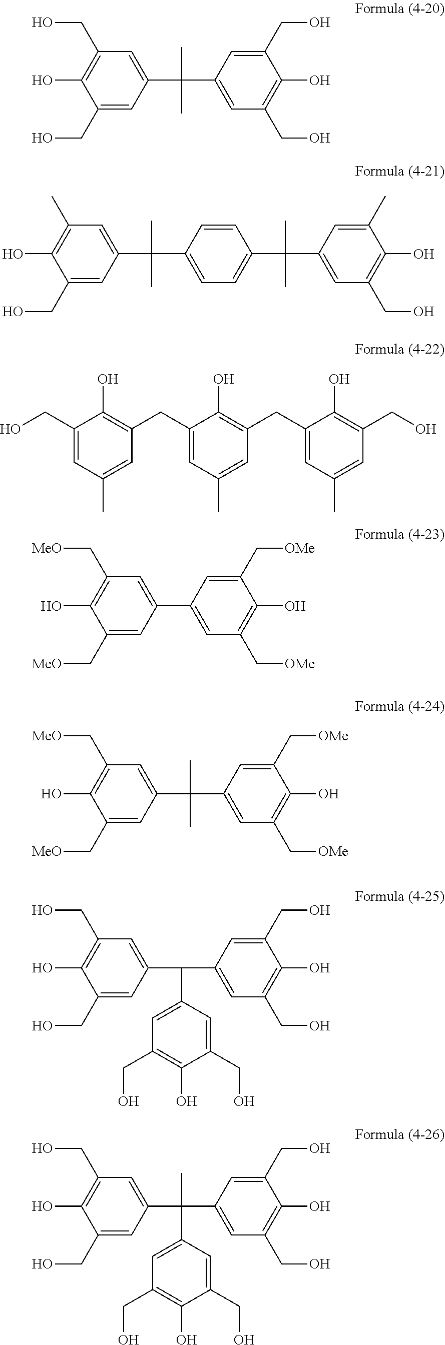

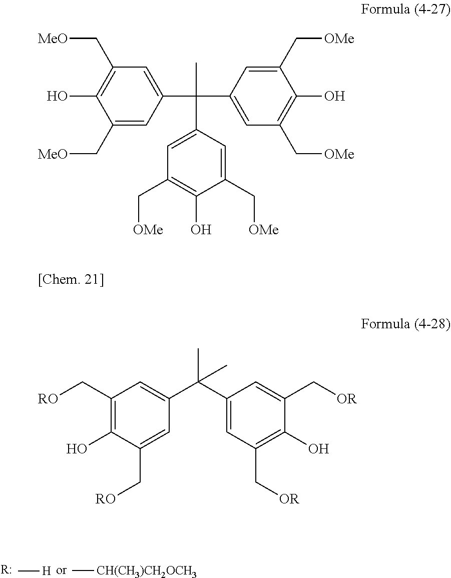

The above compounds are commercially available from ASAHI YUKIZAI CORPORATION or Honshu Chemical Industry Co., Ltd. Of the above crosslinking agents, for example, the compound of the formula (4-23) is available under the product name TMOM-BP from Honshu Chemical Industry Co., Ltd., and the compound of the formula (4-24) is available under the product name TM-BIP-A from ASAHI YUKIZAI CORPORATION.

The amount of the crosslinking agent added varies depending on such factors as the type of the coating solvent used, the type of the substrate used, the solution viscosity that is required, and the film shape that is required; however, it may be 0.001% by mass or more, 0.01% by mass or more, 0.05% by mass or more, 0.5% by mass or more, or 1.0% by mass or more, and 80% by mass or less, 50% by mass or less, 40% by mass or less, 20% by mass or less, or 10% by mass or less, relative to the total solid content. Although the above crosslinking agent may be crosslinked by self-condensation, it may undergo a crosslinking reaction with the crosslinking substituent, when the polymer of the present invention has crosslinking substituents.

A single species of crosslinking agent selected from those mentioned above may be added, or a combination of two or more species of crosslinking agent selected from those mentioned above may be added.

(Acids and/or Salt Thereof, and/or Acid Generator)

The resist underlayer film-forming composition according to the present invention may contain an acid and/or a salt thereof, and/or an acid generator.

Examples of the acid include methanesulfonic acid, p-toluenesulfonic acid, trifluoromethanesulfonic acid, salicylic acid, 5-sulfosalicylic acid, 4-phenol sulfonic acid, camphorsulfonic acid, 4-chlorobenzenesulfonic acid, benzenedisulfonic acid, 1-naphthalenesulfonic acid, carboxylic acid compounds, such as citric acid, benzoic acid, hydroxybenzoic acid, and naphthalenecarboxylic acid, and inorganic acids, such as hydrochloric acid, sulfuric acid, nitric acid, and phosphoric acid.

As the salt, a salt of the acids mentioned above may also be used. Examples of the salt that may be suitably used include, but are not limited to, ammonia derivative salts, such as trimethylamine salts and triethylamine salts, pyridine derivative salts, and morpholine derivative salts.

The acid and/or the salt thereof may be used each alone or in combination of two or more thereof. The incorporated amount thereof ranges usually 0.0001 to 20% by mass, preferably 0.0005 to 10% by mass, and more preferably 0.01 to 5% by mass relative to the total solid content.

Examples of the acid generator include thermal acid generators and photo acid generators.

Examples of the thermal acid generator include 2,4,4,6-tetrabromocyclohexadienone, benzoin tosylate, 2-nitrobenzyl tosylate, K-PURE [registered trademark] series CXC-1612, CXC-1614, TAG-2172, TAG-2179, TAG-2678, TAG2689, and TAG2700 (manufactured by King Industries), SI-45, SI-60, SI-80, SI-100, SI-110, and SI-150 (manufactured by SANSHIN CHEMICAL INDUSTRY CO., LTD.), quaternary ammonium salts of trifluoroacetic acid, and organic sulfonic acid alkyl esters.

The photo acid generator generates an acid when a resist is exposed to light, thereby allowing the acidity of the underlayer film to be adjusted. The use of the photo acid generator is an approach to adjusting the acidity of the underlayer film to the acidity of the resist layer that is formed thereon. Moreover, the shape of a pattern formed in the upper resist layer may be controlled by the adjustment of the acidity of the underlayer film.

Examples of the photo acid generator used in the resist underlayer film-forming composition of the present invention include onium salt compounds, sulfonimide compounds, and di sulfonyldiazomethane compounds.

Examples of the onium salt compounds include iodonium salt compounds, such as diphenyliodonium hexafluorophosphate, diphenyliodonium trifluoromethanesulfonate, diphenyliodonium nonafluoro-n-butanesulfonate, diphenyliodonium perfluoro-n-octanesulfonate, diphenyliodonium camphorsulfonate, bis(4-tert-butylphenyl)iodonium camphorsulfonate, and bis(4-tert-butylphenyl)iodonium trifluoromethanesulfonate, and sulfonium salt compounds, such as triphenylsulfonium hexafluoroantimonate, triphenylsulfonium nonafluoro-n-butanesulfonate, triphenylsulfonium camphorsulfonate, and triphenylsulfonium trifluoromethanesulfonate.

Examples of the sulfonimide compounds include N-(trifluoromethanesulfonyloxy)succinimide, N-(nonafluoro-n-butanesulfonyloxy)succinimide, N-(camphorsulfonyloxy)succinimide, and N-(trifluoromethanesulfonyloxy)naphthalimide.

Examples of the disulfonyldiazomethane compounds include bis(trifluoromethylsulfonyl)diazomethane, bis(cyclohexylsulfonyl)diazomethane, bis(phenylsulfonyl)diazomethane, bis(p-toluenesulfonyl)diazomethane, bis(2,4-dimethylbenzenesulfonyl)diazomethane, and methylsulfonyl-p-toluenesulfonyldiazomethane.

The acid generators may be used each alone or in combination of two or more thereof.

When an acid generator is used, the proportion thereof ranges 0.01 to 10 parts by mass, or 0.1 to 8 parts by mass, or 0.5 to 5 parts by mass, with respect to 100 parts by mass of the solid content in the resist underlayer film-forming composition.

(Surfactants)

The resist underlayer film-forming composition of the present invention may further contain a surfactant. Examples of the surfactant include nonionic surfactants, for example, polyoxyethylene alkyl ethers, such as polyoxyethylene lauryl ether, polyoxyethylene stearyl ether, polyoxyethylene cetyl ether, and polyoxyethylene oleyl ether, polyoxyethylene alkyl aryl ethers, such as polyoxyethylene octyl phenyl ether and polyoxyethylene nonyl phenyl ether, polyoxyethylene/polyoxypropylene block copolymers, sorbitan fatty acid esters, such as sorbitan monolaurate, sorbitan monopalmitate, sorbitan monostearate, sorbitan monooleate, sorbitan trioleate, and sorbitan tristearate, and polyoxyethylene sorbitan fatty acid esters, such as polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate; fluorine surfactants, such as EFTOP [registered trademark] series EF301, EF303, and EF352 (manufactured by Mitsubishi Materials Electronic Chemicals Co., Ltd.), MEGAFACE [registered trademark] series F171, F173, R-30, R-30-N, R-40, and R-40-LM (manufactured by DIC CORPORATION), FLUORAD series FC430 and FC431 (manufactured by Sumitomo 3M Ltd.), and ASAHI GUARD [registered trademark] AG710 and SURFLON [registered trademark] series S-382, SC101, SC102, SC103, SC104, SC105, and SC106 (manufactured by AGC Inc.); and organosiloxane polymer KP341 (manufactured by Shin-Etsu Chemical Co., Ltd.). A single species of surfactant selected from those mentioned above may be used, or a combination of two or more species of surfactants selected from those mentioned above may also be used. For example, the content proportion of the surfactant ranges 0.01% by mass to 5% by mass relative to the solid content in the resist underlayer film-forming composition of the present invention excluding the solvent described later.

[Film Material (Z)]

The polymer (X) according to the present invention may also be used as a crosslinking agent for a film material (Z). Specifically, the resist underlayer film-forming composition according to the present invention further includes a film material (Z) capable of undergoing a crosslinking reaction with the polymer (X). It may be said that the film material (Z) is a film material that can be crosslinked with the polymer (X).

The film material (Z) that is optionally used in the present invention may be any material without limitation as long as it is capable of undergoing a crosslinking reaction with the polymer (X). The film material may be a polymer, an oligomer, or a low-molecular compound having a molecular weight of 1,000 or less. Examples of the crosslink-forming groups present in the film material include, but are not limited to, hydroxy groups, carboxy groups, amino groups, and alkoxy groups.

More specific examples include the film materials (a) to (z) disclosed in the section [Film materials (Y)] of the specification of WO 2021/172295 (Japanese Patent Application No. 2020-033333).

The crosslinkable film material (Z) preferably comprises at least one member selected from the group consisting of:
(Y1) film materials containing an aliphatic ring (for example, (a) above),
(Y2) novolak film materials (for example, (b), (c), (d), (e), (f), (g), (h), (i), (j), (k), and (1) above),
(Y3) polyether film materials (for example, (z) above),
(Y4) polyester film materials (for example, (o) and (p) above),
(Y5) compounds differing from crosslinkable compound (A) (for example, (n), (r), (s), (t), (u), (v), (w), (x), and (y) above),
(Y6) film materials containing an aromatic condensed ring (for example, (q) above),
(Y7) acrylic resins, and
(Y8) methacrylic resins.

When the resist underlayer film-forming composition according to the present invention contains the crosslinkable film material (Z) (a film material or a polymer), the content proportion of the crosslinkable film material (Z) usually ranges 1 to 99.9% by mass, preferably 50 to 99.9% by mass, more preferably 50 to 95% by mass, and still more preferably 50 to 90% by mass relative to the total solid content.

Additives, such as a light absorber, rheology modifier, and adhesion aid, may be further added to the resist underlayer film-forming composition of the present invention. Rheology modifiers are effective for enhancing the fluidity of the underlayer film-forming composition. Adhesion aids are effective for enhancing the adhesion between the underlayer film and a semiconductor substrate or a resist.

(Light Absorber)

As a light absorbers, suitably used may be commercially available light absorbers according to “Kougyouyou Shikiso no Gijutsu to Shijou (Technology and Market of Industrial Dyes)” (CMC Publishing Co., Ltd.) and “Senryou Binran (Dye Handbook)” (edited by The Society of Synthetic Organic Chemistry, Japan), such as, for example, C. I. Disperse Yellow 1, 3, 4, 5, 7, 8, 13, 23, 31, 49, 50, 51, 54, 60, 64, 66, 68, 79, 82, 88, 90, 93, 102, 114, and 124; C. I. Disperse Orange 1, 5, 13, 25, 29, 30, 31, 44, 57, 72, and 73; C. I. Disperse Red 1, 5, 7, 13, 17, 19, 43, 50, 54, 58, 65, 72, 73, 88, 117, 137, 143, 199, and 210; C. I. Disperse Violet 43; C. I. Disperse Blue 96; C. I. Fluorescent Brightening Agent 112, 135, and 163; C. I. Solvent Orange 2 and 45; C. I. Solvent Red 1, 3, 8, 23, 24, 25, 27, and 49; C. I. Pigment Green 10; and C. I. Pigment Brown 2. The light absorber is usually added in a proportion of 10% by mass or less, preferably 5% by mass or less, relative to the total solid content in the resist underlayer film-forming composition.

(Rheology Modifier)

The rheology modifier may be added mainly to enhance the fluidity of the resist underlayer film-forming composition and thereby, particularly in the baking step, to enhance the uniformity in thickness of the resist underlayer film and to increase the filling performance of the resist underlayer film-forming composition with respect to the inside of holes. Specific examples thereof include phthalic acid derivatives, such as dimethyl phthalate, diethyl phthalate, diisobutyl phthalate, dihexyl phthalate, and butyl isodecyl phthalate; adipic acid derivatives, such as di-n-butyl adipate, diisobutyl adipate, diisooctyl adipate, and octyl decyl adipate; maleic acid derivatives, such as di-n-butyl maleate, diethyl maleate, and dinonyl maleate; oleic acid derivatives, such as methyl oleate, butyl oleate, and tetrahydrofurfuryl oleate; and stearic acid derivatives, such as n-butyl stearate and glyceryl stearate. The rheology modifier is usually added in a proportion of less than 30% by mass relative to the total solid content in the resist underlayer film-forming composition.

(Adhesion Aid)

The adhesion aid may be added mainly to enhance the adhesion between the resist underlayer film-forming composition and a substrate or a resist and thereby to prevent the detachment of the resist particularly during development. Specific examples thereof include chlorosilanes, such as trimethylchlorosilane, dimethylmethylolchlorosilane, methyldiphenylchlorosilane, and chloromethyldimethylchlorosilane; alkoxysilanes, such as trimethylmethoxysilane, dimethyldiethoxysilane, methyldimethoxysilane, dimethylmethylolethoxysilane, diphenyldimethoxysilane, and phenyltriethoxysilane; silazanes, such as hexamethyldisilazane, N,N′-bis(trimethylsilyl)urea, dimethyltrimethylsilylamine, and trimethylsilylimidazole; silanes, such as methyloltrichlorosilane, γ-chloropropyltrimethoxysilane, γ-aminopropyltriethoxysilane, and γ-glycidoxypropyltrimethoxysilane; heterocyclic compounds, such as benzotriazole, benzimidazole, indazole, imidazole, 2-mercaptobenzimidazole, 2-mercaptobenzothiazole, 2-mercaptobenzoxazole, urazole, thiouracil, mercaptoimidazole, and mercaptopyrimidine; and urea or thiourea compounds, such as 1,1-dimethylurea and 1,3-dimethylurea. The adhesion aid is usually added in a proportion of less than 5% by mass, preferably less than 2% by mass, relative to the total solid content in the resist underlayer film-forming composition.

The solid content in the resist underlayer film-forming composition of the present invention ranges usually 0.1 to 70% by mass, and preferably 0.1 to 60% by mass. The solid content is the proportion of all the components constituting the resist underlayer film-forming composition except the solvent. The proportion of the polymer in the solid content ranges 1 to 100% by mass, 1 to 99.9% by mass, 50 to 99.9% by mass, 50 to 95% by mass, or 50 to 90% by mass, in the order of increasing preference.

One of the measures for evaluating whether the resist underlayer film-forming composition is a uniform solution is to pass the composition through a predetermined microfilter. The resist underlayer film-forming composition according to the present invention can be passed through a microfilter having a pore size of 0.1 and exhibits a uniform solution state.

Examples of the microfilter material include fluororesins, such as PTFE (polytetrafluoroethylene) and PFA (tetrafluoroethylene/perfluoroalkyl vinyl ether copolymer), PE (polyethylene), UPE (ultrahigh molecular weight polyethylene), PP (polypropylene), PSF (polysulfone), PES (polyethersulfone), and nylon, and PTFE (polytetrafluoroethylene) is preferable.

[Resist Underlayer Film]

A resist underlayer film may be formed as described below using the resist underlayer film-forming composition according to the present invention.

The resist underlayer film-forming composition of the present invention is applied with an appropriate technique, such as a spinner or a coater, onto a semiconductor device substrate (such as, for example, a silicon wafer substrate, a silicon dioxide-coated substrate (a SiO₂ substrate), a silicon nitride substrate (a SiN substrate), a silicon oxynitride substrate (a SiON substrate), a titanium nitride substrate (a TiN substrate), a tungsten substrate (a W substrate), a glass substrate, an ITO substrate, a polyimide substrate, or a low-dielectric constant material (low-k material)-coated substrate), and the coating is baked using a heating device, such as a hot plate, to form a resist underlayer film. The baking conditions are appropriately selected from baking temperatures of 80° C. to 600° C. and amounts of baking time of 0.3 to 60 minutes. The baking temperature is preferably 150° C. to 350° C., and the baking time is preferably 0.5 to 2 minutes. The atmosphere gas at the time of baking may be air or an inert gas, such as nitrogen or argon. Here, the film thickness of the underlayer film that is formed is, for example, within the range of 10 to 1000 nm, or 20 to 500 nm, or 30 to 400 nm, or 50 to 300 nm. Moreover, a replica (mold replica) of a quartz imprinting mold may be produced by using a quartz substrate as the substrate.

Moreover, an adhesion layer and/or a silicone layer containing 99% by mass or less, or 50% by mass or less of Si may be formed on the resist underlayer film according to the present invention by application or deposition. For example, an adhesion layer according to JP 2013-202982 A or Japanese Patent No. 5827180 may be formed, or a silicon-containing resist underlayer film (inorganic resist underlayer film)-forming composition according to WO 2009/104552 A1 may be applied by spin coating. Moreover, a Si-based inorganic material film may be formed by such a method as a CVD method.

The resist underlayer film-forming composition according to the present invention may be applied onto a semiconductor substrate having a stepped region and a stepless region (the so-called stepped substrate) and may be baked to reduce the difference in height between the stepped region and the stepless region.

[Process for Manufacturing Semiconductor Device]

The process for manufacturing a semiconductor device according to the present invention comprises the steps of:
forming a resist underlayer film using the resist underlayer film-forming composition according to the present invention;
forming a resist film on the resist underlayer film;
forming a resist pattern by applying a light or electron beam to the resist film followed by development;
forming a pattern in the resist underlayer film by etching the resist underlayer film through the formed resist pattern; and
processing the semiconductor substrate through the patterned resist underlayer film.

Moreover, the process for manufacturing a semiconductor device according to the present invention comprises the steps of:
forming a resist underlayer film using the resist underlayer film-forming composition according to the present invention;
forming a hard mask on the resist underlayer film;
forming a resist film on the hard mask;
applying a light or electron beam to the resist film followed by development to form a resist pattern;
etching the hard mask through the formed resist pattern to form a patterned hard mask; and
etching the resist underlayer film through the patterned hard mask to form a patterned resist underlayer film; and
processing the semiconductor substrate through the patterned resist underlayer film.

The step of forming a resist underlayer film using the resist underlayer film-forming composition according to the present invention is as described hereinabove.

As a second resist underlayer film, an organopolysiloxane film may be formed on the resist underlayer film resulting from the above step, and a resist pattern may be formed thereon. The second resist underlayer film may be a SiON film or a SiN film formed by a deposition method, such as CVD or PVD. Moreover, a bottom anti-reflective coating (BARC) as a third resist underlayer film may be formed on the second resist underlayer film. The third resist underlayer film may be a resist shape correction film having no antireflection function.

In the step of forming a resist pattern, the exposure is performed through a mask (a reticle) for forming a predetermined pattern, or is carried out by direct drawing. For example, g-ray, i-ray, KrF excimer laser, ArF excimer laser, EUV, or electron beam may be used as the exposure source. After the exposure, post exposure baking is performed as required. Subsequently, the latent image is developed with a developing solution (for example, a 2.38% by mass aqueous tetramethylammonium hydroxide solution), and the pattern is further rinsed with a rinsing solution or pure water to remove the developing solution used. Subsequently, post-baking is performed to dry the resist pattern and to enhance the adhesion to the base.

The etching step following the resist pattern formation is performed by dry etching. The etching gas used for dry etching may be, for example, CHF₃, CF₄, or C₂F₆ for the second resist underlayer film (the organopolysiloxane film); it may be, for example, O₂, N₂O, or NO₂ for the first resist underlayer film formed from the resist underlayer film-forming composition of the present invention; and it may be, for example, CHF₃, CF₄, or C₂F₆ for a surface having a step, or a concave portion and/or a convex portion. Moreover, argon, nitrogen, or carbon dioxide may be mixed with the above gases.

[Formation of Resist Underlayer Film by Nanoimprinting Method]

The step of forming a resist underlayer film may also be performed by a nanoimprinting method. This method comprises the steps of:
applying a curable composition onto a resist underlayer film formed;
bringing the curable composition into contact with a mold;
applying a light or electron beam to the curable composition to form a cured film; and separating the cured film from the mold.

The polymer (X) according to the present invention is expected to exhibit a good permeability to gases, such as He, Hz, Nz, and air, and exhibits a good gap-filling property, hardness, and bend resistance. It permits appropriate control of optical constants and etching rates suited for the process by altering the molecular skeleton. For example, the details are as disclosed in the section [Formation of resist underlayer film by nanoimprinting method] in the description of WO 2021/172295 (Japanese Patent Application No. 2020-033333).

### EXAMPLES

Hereinbelow, specific examples of the compositions according to the present invention will be described with reference to the following Examples and other experiments. However, it should not be construed that the scope of the present invention is limited thereto.

The following are the apparatus and conditions used in the measurement of the weight average molecular weights of reaction products obtained in Synthesis Examples described later.
Apparatus: HLC-8320 GPC manufactured by TOSOH CORPORATION
GPC columns: TSKgel Super-Multipore HZ-N (two columns)
Column temperature: 40° C.
Flow rate: 0.35 mL/min
Eluent: THF
Standard samples: polystyrene

The chemical structure (illustrative) and abbreviation of the representative raw materials used are as follows.

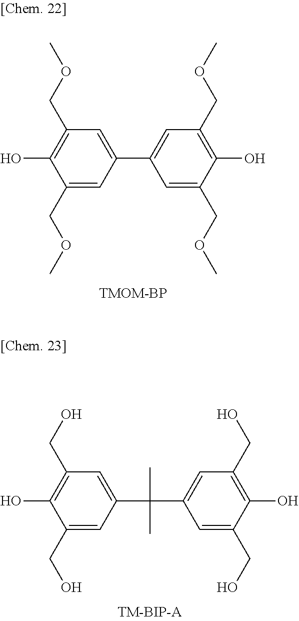 [SMILES: COCc1cc(-c2cc(COC)c(O)c(COC)c2)cc(COC)c1O ; CC(C)(c1cc(CO)c(O)c(CO)c1)c1cc(CO)c(O)c(CO)c1]

### Synthesis Example 1

A flask was charged with 12.00 g of TMOM-BP (Honshu Chemical Industry Co., Ltd.), 7.23 g of 4,4-difluorobenzophenone (Tokyo Chemical Industry Co., Ltd., hereinafter DFBP), 4.78 g of potassium carbonate (manufactured by FUJIFILM Wako Pure Chemical Corporation), and 56.01 g of N-methylpyrrolidone (hereinafter NMP). Subsequently, the mixture was heated to 150° C. under nitrogen, and allowed to react for about 4.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-1). GPC analysis showed that the resin had a weight average molecular weight Mw in terms of polystyrene of about 7,300. The resin obtained was dissolved into propylene glycol monomethyl ether (hereinafter PGMEA), and subjected to ion exchange treatment for 4 hours using a cation exchange resin and an anion exchange resin. A target compound solution was thus obtained.

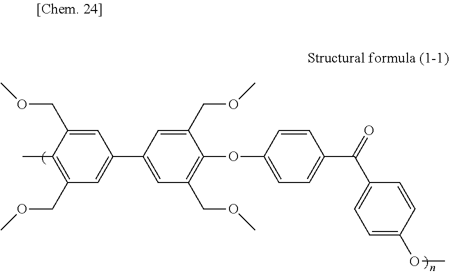

### Synthesis Example 2

A flask was charged with 15.00 g of TMOM-BP, 4.52 g of DFBP, 4.23 g of 4,4′-difluorodiphenylmethane, 2.99 g of potassium carbonate, and 52.51 g of NMP. Subsequently, the mixture was heated to 150° C. under nitrogen, and allowed to react for about 4.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-2). GPC analysis showed that the resin had a weight average molecular weight Mw in terms of polystyrene of about 5,100. The resin obtained was dissolved into PGMEA, and subjected to ion exchange treatment for 4 hours using a cation exchange resin and an anion exchange resin. A target compound solution was thus obtained.

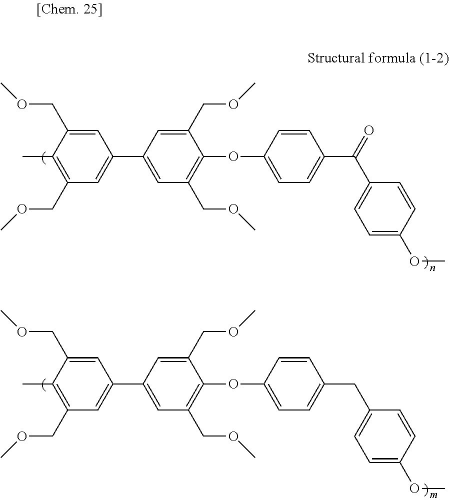

### Synthesis Example 3

A flask was charged with 12.00 g of TMOM-BP, 11.60 g of 9,9-bis(4-hydroxyphenyl)fluorene (Tokyo Chemical Industry Co., Ltd.), 14.45 g of DFBP, 9.55 g of potassium carbonate, and 111.06 g of NMP. Subsequently, the mixture was heated to 150° C. under nitrogen, and allowed to react for about 3.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-3). GPC analysis showed that the resin had a weight average molecular weight Mw in terms of polystyrene of about 6,500. The resin obtained was dissolved into PGMEA, and subjected to ion exchange treatment for 4 hours using a cation exchange resin and an anion exchange resin. A target compound solution was thus obtained.

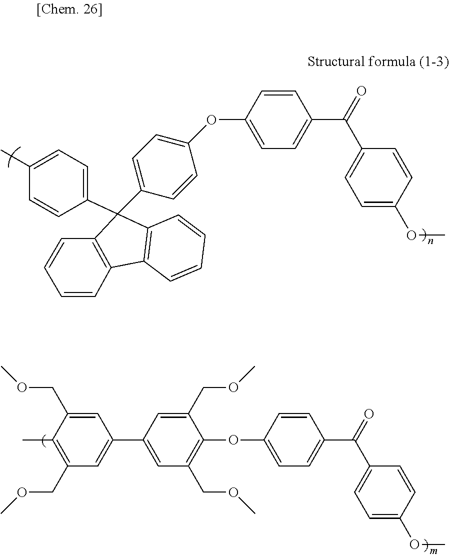

### Synthesis Example 4

A flask was charged with 15.00 g of TMOM-BP, 6.63 g of 1,5-dihydroxynaphthalene (Tokyo Chemical Industry Co., Ltd.), 18.06 g of DFBP, 11.93 g of potassium carbonate, and 120.45 g of NMP. Subsequently, the mixture was heated to 150° C. under nitrogen, and allowed to react for about 1.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-4). GPC analysis showed that the resin had a weight average molecular weight Mw in terms of polystyrene of about 7,600. The resin obtained was dissolved into propylene glycol monomethyl ether (hereinafter PGME), and subjected to ion exchange treatment for 4 hours using a cation exchange resin and an anion exchange resin. A target compound solution was thus obtained.

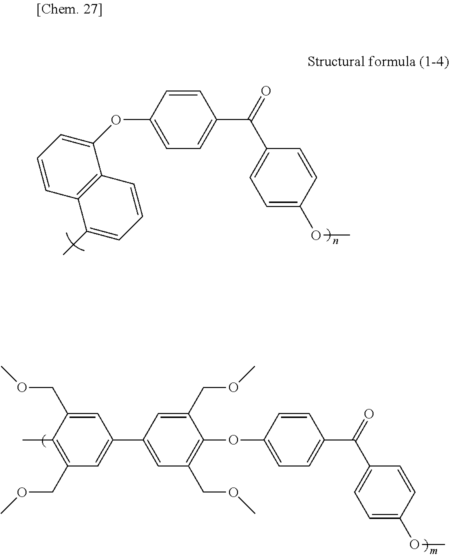

### Synthesis Example 5

A flask was charged with 15.00 g of TMOM-BP, 2.36 g of 1,4-difluorobenzene (Tokyo Chemical Industry Co., Ltd., hereinafter DFB), 4.52 g of DFBP, 5.97 g of potassium carbonate, and 25.49 g of NMP. Subsequently, the mixture was heated to 150° C. under nitrogen, and allowed to react for about 3 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-5). GPC analysis showed that the resin had a weight average molecular weight Mw in terms of polystyrene of about 15,200. The resin obtained was dissolved into cyclohexanone (hereinafter CYH), and subjected to ion exchange treatment for 4 hours using a cation exchange resin and an anion exchange resin. A target compound solution was thus obtained.

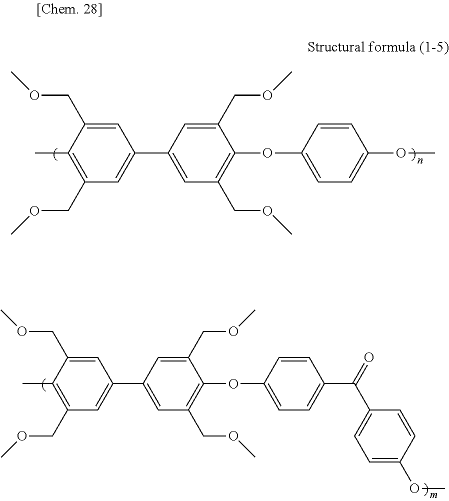

### Synthesis Example 6

A flask was charged with 10.00 g of TMOM-BP, 1.10 g of 1-naphthol, 7.53 g of DFBP, 4.97 g of potassium carbonate, and 55.07 g of NMP. Subsequently, the mixture was heated to 150° C. under nitrogen, and allowed to react for about 4.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-6). GPC analysis showed that the resin had a weight average molecular weight Mw in terms of polystyrene of about 5,700. The resin obtained was dissolved into PGMEA, and subjected to ion exchange treatment for 4 hours using a cation exchange resin and an anion exchange resin. A target compound solution was thus obtained.

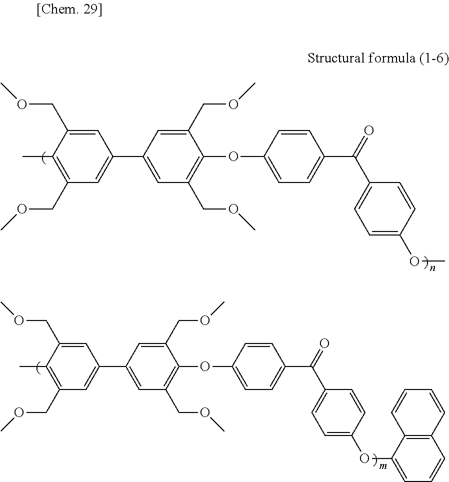

### Synthesis Example 7

A flask was charged with 12.00 g of TMOM-BP, 0.81 g of 4-fluorostyrene (Tokyo Chemical Industry Co., Ltd.), 5.78 g of DFBP, 4.77 g of potassium carbonate, and 54.51 g of NMP. Subsequently, the mixture was heated to 150° C. under nitrogen, and allowed to react for about 4.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-8). GPC analysis showed that the resin had a weight average molecular weight Mw in terms of polystyrene of about 14,400. The resin obtained was dissolved into PGMEA, and subjected to ion exchange treatment for 4 hours using a cation exchange resin and an anion exchange resin. A target compound solution was thus obtained.

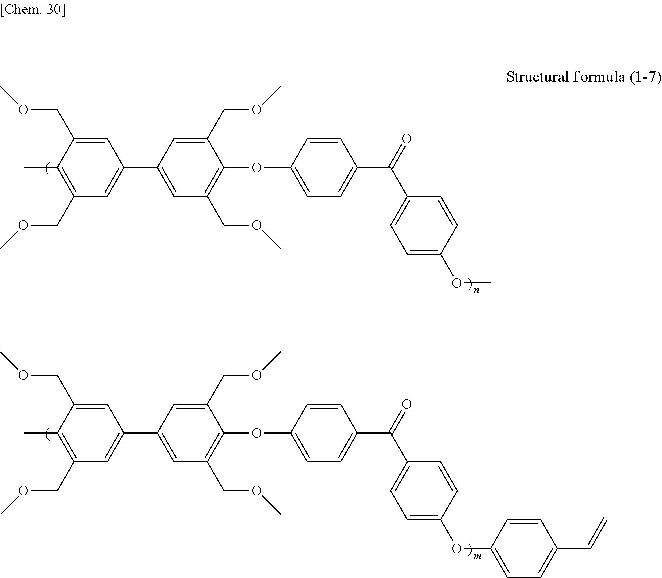

### Synthesis Example 8

A flask was charged with 12.00 g of TMOM-BP, 2.64 g of 2,2-biphenol (Tokyo Chemical Industry Co., Ltd.), 5.78 g of DFBP, 10.32 g of potassium carbonate, and 78.93 g of NMP. Subsequently, the mixture was heated to 150° C. under nitrogen, and allowed to react for about 4 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-9). GPC analysis showed that the resin had a weight average molecular weight Mw in terms of polystyrene of about 5,000. The resin obtained was dissolved into PGMEA, and subjected to ion exchange treatment for 4 hours using a cation exchange resin and an anion exchange resin. A target compound solution was thus obtained.

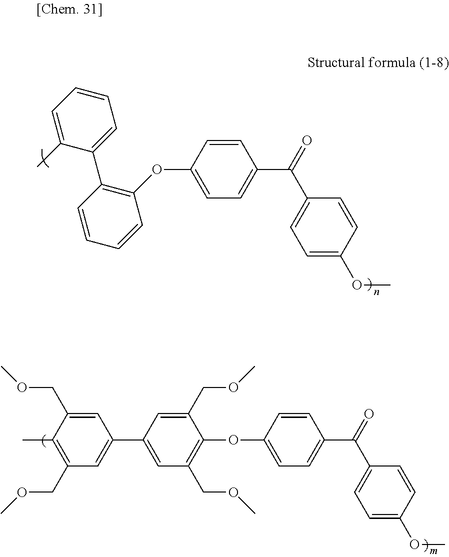

### Synthesis Example 9

A flask was charged with 12.00 g of TMOM-BP, 4.30 g of 1,1,1-tris(4-hydroxyphenyl)ethane (Tokyo Chemical Industry Co., Ltd.), 10.32 g of DFBP, 8.86 g of potassium carbonate, and 82.80 g of NMP. Subsequently, the mixture was heated to 150° C. under nitrogen, and allowed to react for about 1.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (1-10). GPC analysis showed that the resin had a weight average molecular weight Mw in terms of polystyrene of about 7,500. The resin obtained was dissolved into PGMEA, and subjected to ion exchange treatment for 4 hours using a cation exchange resin and an anion exchange resin. A target compound solution was thus obtained.

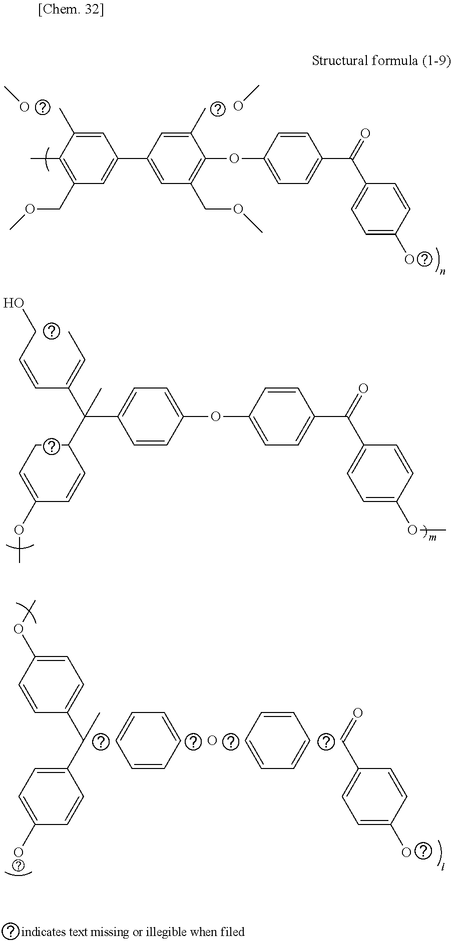

### Synthesis Example 10

A flask was charged with 8.00 g of TMOM-BP, 1.92 g of TM-BIP-A, 6.02 g of DFBP, 3.98 g of potassium carbonate, and 46.48 g of NMP. Subsequently, the mixture was heated to 100° C. under nitrogen, and allowed to react for about 5 hours. After the reaction was terminated, potassium carbonate was removed by filtration. The filtrate obtained was neutralized by the addition of 1 N—HCl and was stirred for a while. The resultant diluted solution was added dropwise to a methanol/water=70/30 (vol/vol) solution to reprecipitate the product. The solution was suction filtered. The precipitate thus obtained was dried to give a resin (1-11). GPC analysis showed that the resin had a weight average molecular weight Mw in terms of polystyrene of about 4,400. The resin obtained was dissolved into PGMEA, and subjected to ion exchange treatment for 4 hours using a cation exchange resin and an anion exchange resin. A target compound solution was thus obtained.

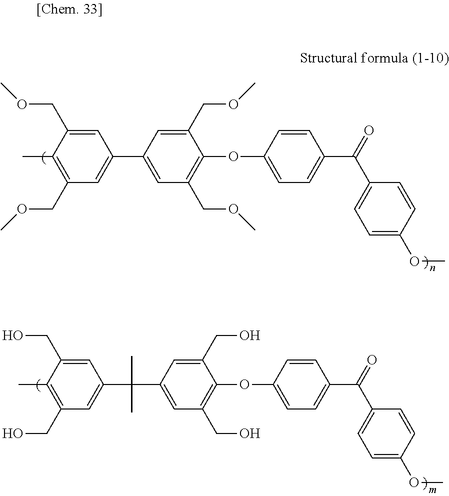

### Synthesis Example 11

A 100 mL flask was charged with 8.00 g of carbazole (manufactured by Tokyo Chemical Industry Co., Ltd.), 8.63 g of 9-fluorenone (manufactured by Tokyo Chemical Industry Co., Ltd.), 2.30 g of methanesulfonic acid (manufactured by Tokyo Chemical Industry Co., Ltd.), and 18.93 g of PGMEA. The mixture was heated under nitrogen to reflux. After about 1.5 hours, the product was precipitated in methanol and was dried to give a polymer (1-12). GPC analysis showed that the resin had a weight average molecular weight Mw in terms of polystyrene of about 2,600. The resin obtained was dissolved into PGMEA, and subjected to ion exchange treatment for 4 hours using a cation exchange resin and an anion exchange resin. A target polymer solution was thus obtained.

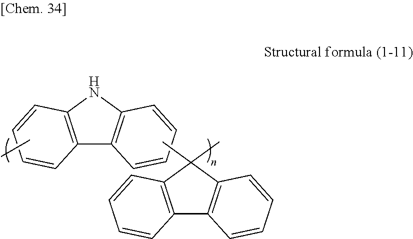

### Comparative Synthesis Example 1

A flask was charged with 5.00 g of 4,4′-dihydroxy 3,3′,5,5′-tetramethylbiphenyl, 4.50 g of DFBP, 2.97 g of potassium carbonate, and 29.11 g of NMP. Subsequently, the mixture was heated to 150° C. under nitrogen, and allowed to react for about 4.5 hours. After the reaction was terminated, potassium carbonate was removed by filtration. The filtrate obtained was neutralized by the addition of 1 N—HCl and was stirred for a while. The resultant diluted solution was added dropwise to a methanol/water=90/10 (vol/vol) solution to reprecipitate the product. The solution was suction filtered. The precipitate thus obtained was dried to give a resin (2-1). GPC analysis showed that the resin had a weight average molecular weight Mw in terms of polystyrene of about 1,500. The resin obtained was dissolved into PGMEA, and subjected to ion exchange treatment for 4 hours using a cation exchange resin and an anion exchange resin. A target compound solution was thus obtained.

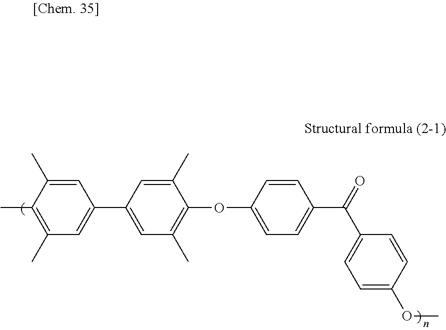

### Example 1

The resin solution (solid content: 17.17% by mass) was obtained in Synthesis Example 1. To 4.97 g of this resin solution, 0.17 g of TMOM-BP (Honshu Chemical Industry Co., Ltd.), 1.95 g of a 2% by mass PGME solution of pyridinium p-hydroxybenzenesulfonate, 0.09 g of a 1% by mass PGMEA solution of a surfactant (MEGAFACE R-40, DIC CORPORATION), 5.57 g of PGMEA, and 2.93 g of PGME were added and dissolved. The resultant solution was filtered through a polytetrafluoroethylene microfilter having a pore size of 0.1 μm. A solution of a resist underlayer film-forming composition was thus prepared.

### Example 2

The resin solution (solid content: 17.17% by mass) was obtained in Synthesis Example 1. To 5.93 g of this resin solution, 1.53 g of a 2% by mass PGME solution of pyridinium p-hydroxybenzenesulfonate, 0.10 g of a 1% by mass PGMEA solution of a surfactant (MEGAFACE R-40, DIC CORPORATION), 4.75 g of PGMEA, and 2.69 g of PGME were added and dissolved. The resultant solution was filtered through a polytetrafluoroethylene microfilter having a pore size of 0.1 μm. A solution of a resist underlayer film-forming composition was thus prepared.

### Example 3

The resin solution (solid content: 17.17% by mass) was obtained in Synthesis Example 1. To 13.96 g of this resin solution, 0.24 g of a 1% by mass PGMEA solution of a surfactant (MEGAFACE R-40, DIC CORPORATION), 0.52 g of PGMEA, and 5.28 g of PGME were added and dissolved. The resultant solution was filtered through a polytetrafluoroethylene microfilter having a pore size of 0.1 μm. A solution of a resist underlayer film-forming composition was thus prepared.

### Example 4

The resin solution (solid content: 14.96% by mass) was obtained in Synthesis Example 2. To 5.70 g of this resin solution, 0.17 g of TMOM-BP, 1.28 g of a 2% by mass PGME solution of pyridinium p-hydroxybenzenesulfonate, 0.09 g of a 1% by mass PGMEA solution of a surfactant (MEGAFACE R-40, DIC CORPORATION), 4.83 g of PGMEA, and 2.93 g of PGME were added and dissolved. The resultant solution was filtered through a polytetrafluoroethylene microfilter having a pore size of 0.1 μm. A solution of a resist underlayer film-forming composition was thus prepared.

### Example 5

The resin solution (solid content: 17.90% by mass) was obtained in Synthesis Example 3. To 4.77 g of this resin solution, 0.17 g of TMOM-BP, 1.28 g of a 2% by mass PGME solution of pyridinium p-hydroxybenzenesulfonate, 0.09 g of a 1% by mass PGMEA solution of a surfactant (MEGAFACE R-40, DIC CORPORATION), 5.77 g of PGMEA, and 2.91 g of PGME were added and dissolved. The resultant solution was filtered through a polytetrafluoroethylene microfilter having a pore size of 0.1 μm. A solution of a resist underlayer film-forming composition was thus prepared.

### Example 6

The resin solution (solid content: 17.39% by mass) was obtained in Synthesis Example 4. To 4.90 g of this resin solution, 0.17 g of TMOM-BP, 1.28 g of a 2% by mass PGME solution of pyridinium p-hydroxybenzenesulfonate, 0.09 g of a 1% by mass PGMEA solution of a surfactant (MEGAFACE R-40, DIC CORPORATION), 4.10 g of PGMEA, and 4.46 g of PGME were added and dissolved. The resultant solution was filtered through a polytetrafluoroethylene microfilter having a pore size of 0.1 μm. A solution of a resist underlayer film-forming composition was thus prepared.

### Example 7

The resin solution (solid content: 17.40% by mass) was obtained in Synthesis Example 5. To 4.90 g of this resin solution, 0.17 g of TMOM-BP, 1.28 g of a 2% by mass PGME solution of pyridinium p-hydroxybenzenesulfonate, 0.09 g of a 1% by mass PGMEA solution of a surfactant (MEGAFACE R-40, DIC CORPORATION), 4.10 g of PGMEA, 1.54 g of PGME, and 2.93 g of CYH were added and dissolved. The resultant solution was filtered through a polytetrafluoroethylene microfilter having a pore size of 0.1 μm. A solution of a resist underlayer film-forming composition was thus prepared.

### Example 8

The resin solution (solid content: 21.61% by mass) was obtained in Synthesis Example 6. To 3.76 g of this resin solution, 0.16 g of TMOM-BP, 1.22 g of a 2% by mass PGME solution of pyridinium p-hydroxybenzenesulfonate, 0.08 g of a 1% by mass PGMEA solution of a surfactant (MEGAFACE R-40, DIC CORPORATION), 3.27 g of PGMEA, and 1.51 g of PGME were added and dissolved. The resultant solution was filtered through a polytetrafluoroethylene microfilter having a pore size of 0.1 μm. A solution of a resist underlayer film-forming composition was thus prepared.

### Example 9

The resin solution (solid content: 19.85% by mass) was obtained in Synthesis Example 7. To 4.09 g of this resin solution, 0.16 g of TMOM-BP, 1.22 g of a 2% by mass PGME solution of pyridinium p-hydroxybenzenesulfonate, 0.08 g of a 1% by mass PGMEA solution of a surfactant (MEGAFACE R-40, DIC CORPORATION), 2.94 g of PGMEA, and 1.51 g of PGME were added and dissolved. The resultant solution was filtered through a polytetrafluoroethylene microfilter having a pore size of 0.1 μm. A solution of a resist underlayer film-forming composition was thus prepared.

### Example 10

The resin solution (solid content: 20.06% by mass) was obtained in Synthesis Example 8. To 4.05 g of this resin solution, 0.16 g of TMOM-BP, 1.22 g of a 2% by mass PGME solution of pyridinium p-hydroxybenzenesulfonate, 0.08 g of a 1% by mass PGMEA solution of a surfactant (MEGAFACE R-40, DIC CORPORATION), 2.98 g of PGMEA, and 1.51 g of PGME were added and dissolved. The resultant solution was filtered through a polytetrafluoroethylene microfilter having a pore size of A solution of a resist underlayer film-forming composition was thus prepared.

### Example 11

The resin solution (solid content: 19.38% by mass) was obtained in Synthesis Example 9. To 4.19 g of this resin solution, 0.16 g of TMOM-BP, 1.22 g of a 2% by mass PGME solution of pyridinium p-hydroxybenzenesulfonate, 0.08 g of a 1% by mass PGMEA solution of a surfactant (MEGAFACE R-40, DIC CORPORATION), 2.84 g of PGMEA, and 1.51 g of PGME were added and dissolved. The resultant solution was filtered through a polytetrafluoroethylene microfilter having a pore size of 0.1 μm. A solution of a resist underlayer film-forming composition was thus prepared.

### Example 12

The resin solution (solid content: 17.52% by mass) was obtained in Synthesis Example 10. To 4.87 g of this resin solution, 0.17 g of TMOM-BP, 1.28 g of a 2% by mass PGME solution of pyridinium p-hydroxybenzenesulfonate, 0.09 g of a 1% by mass PGMEA solution of a surfactant (MEGAFACE R-40, DIC CORPORATION), 5.66 g of PGMEA, and 2.91 g of PGME were added and dissolved. The resultant solution was filtered through a polytetrafluoroethylene microfilter having a pore size of 0.1 μm. A solution of a resist underlayer film-forming composition was thus prepared.

### Example 13

The resin solution (solid content: 30.00% by mass) was obtained in Synthesis Example 11. To 4.33 g of this resin solution, 1.51 g of the resin solution (solid content: 17.17% by mass) obtained in Synthesis Example 1, 1.95 g of a 2% by mass PGME solution of pyridinium p-hydroxybenzenesulfonate, 0.13 g of a 1% by mass PGMEA solution of a surfactant (MEGAFACE R-40, DIC CORPORATION), 10.31 g of PGMEA, and 1.77 g of PGME were added and dissolved. The resultant solution was filtered through a polytetrafluoroethylene microfilter having a pore size of 0.1 μm. A solution of a resist underlayer film-forming composition was thus prepared.

### Comparative Example 1

The resin solution (solid content: 18.37% by mass) was obtained in Comparative Synthesis Example 1. To 5.31 g of this resin solution, 0.19 g of TMOM-BP, 1.46 g of a 2% by mass PGME solution of pyridinium p-hydroxybenzenesulfonate, 0.10 g of a 1% by mass PGMEA solution of a surfactant (MEGAFACE R-40, DIC CORPORATION), 5.21 g of PGMEA, and 2.71 g of PGME were added and dissolved. The resultant solution was filtered through a polytetrafluoroethylene microfilter having a pore size of 0.1 μm. A solution of a resist underlayer film-forming composition was thus prepared.

### Comparative Example 2

The resin solution (solid content: 30.00% by mass) was obtained in Synthesis Example 11. To 4.33 g of this resin solution, 0.26 g of TMOM-BP, 1.95 g of a 2% by mass PGME solution of pyridinium p-hydroxybenzenesulfonate, 0.13 g of a 1% by mass PGMEA solution of a surfactant (MEGAFACE R-40, DIC CORPORATION), 11.56 g of PGMEA, and 1.77 g of PGME were added and dissolved. The resultant solution was filtered through a polytetrafluoroethylene microfilter having a pore size of 0.1 μm. A solution of a resist underlayer film-forming composition was thus prepared.

(Test of Dissolution into Resist Solvent)

Each of the solutions of a resist underlayer film-forming composition prepared in Comparative Example 1 and Examples 1 to 12 was applied onto a silicon wafer using a spin coater. The applied film was baked on a hot plate at 240° C., 350° C., or 400° C. for 60 seconds to form a resist underlayer film (film thickness: 200 nm). The resultant resist underlayer films were soaked in a general-purpose thinner, specifically, PGME/PGMEA=7/3, to examine the resistance to the solvent (Table 1). The results are expressed by ∘ when the loss in film thickness after immersion was less than 1%, and x when the loss in film thickness after immersion was 1% or more.

TABLE 1
Dissolution test

| | | Results |
|---|---|---|
| Comparative Example 1 | 240° C.-Baked film | X |
| Comparative Example 1 | 350° C.-Baked film | ◯ |
| Example 1 | 240° C.-Baked film | ◯ |
| Example 1 | 350° C.-Baked film | ◯ |
| Example 2 | 240° C.-Baked film | ◯ |
| Example 2 | 350° C.-Baked film | ◯ |
| Example 3 | 240° C.-Baked film | ◯ |
| Example 3 | 350° C.-Baked film | ◯ |
| Example 3 | 400° C.-Baked film | ◯ |
| Example 4 | 240° C.-Baked film | ◯ |
| Example 5 | 240° C.-Baked film | ◯ |
| Example 6 | 240° C.-Baked film | ◯ |
| Example 7 | 240° C.-Baked film | ◯ |
| Example 8 | 240° C.-Baked film | ◯ |
| Example 9 | 240° C.-Baked film | ◯ |
| Example 10 | 240° C.-Baked film | ◯ |
| Example 11 | 240° C.-Baked film | ◯ |
| Example 12 | 240° C.-Baked film | ◯ |

From the comparison between Example 1 and Comparative Example 1, in which the baking temperature was both 240° C., the Example gave a good curability, whereas Comparative Example resulted in insufficient curability. That is, introduction of specific crosslinking groups into the polymer brought about significant advantages on its curability. Moreover, in general, solvent resistance cannot be obtained by low-temperature baking unless a polymer is baked in combination with a crosslinking agent and a catalyst. However, as demonstrated in Examples 1 to 12, introducing specific crosslinking groups into the polymers provided a sufficient curability with all of the cases, where a crosslinking agent and an acid catalyst were used, only an acid catalyst was used, and neither a crosslinking agent nor an acid catalyst was used.

(Measurement of Optical Constants)

Each of the solutions of a resist underlayer film-forming composition prepared in Comparative Example 1 and Examples 1 to 12 was applied onto a silicon wafer using a spin coater. The applied film was baked on a hot plate at 240° C., 350° C., or 400° C. for 60 seconds to form a resist underlayer film (film thickness: 50 nm). The resultant resist underlayer films were analyzed with a spectroscopic ellipsometer to measure the refractive index (n value) and the optical absorption coefficient (k value, also called the attenuation coefficient) at a wavelength of 193 nm (Table 2).

TABLE 2
Refractive index n and optical absorption coefficient k

| | | n/k@193 nm |
|---|---|---|
| Comparative Example 1 | 350° C.-Baked film | 1.49/0.56 |
| Example 1 | 240° C.-Baked film | 1.50/0.49 |
| Example 1 | 350° C.-Baked film | 1.47/0.50 |
| Example 2 | 240° C.-Baked film | 1.51/0.51 |
| Example 2 | 350° C.-Baked film | 1.48/0.51 |
| Example 3 | 240° C.-Baked film | 1.50/0.49 |
| Example 3 | 350° C.-Baked film | 1.48/0.50 |
| Example 3 | 400° C.-Baked film | 1.46/0.50 |
| Example 4 | 240° C.-Baked film | 1.45/0.45 |
| Example 5 | 240° C.-Baked film | 1.46/0.61 |
| Example 6 | 240° C.-Baked film | 1.48/0.50 |
| Example 7 | 240° C.-Baked film | 1.46/0.47 |
| Example 8 | 240° C.-Baked film | 1.49/0.50 |
| Example 9 | 240° C.-Baked film | 1.51/0.49 |
| Example 10 | 240° C.-Baked film | 1.46/0.50 |
| Example 11 | 240° C.-Baked film | 1.43/0.55 |
| Example 12 | 240° C.-Baked film | 1.39/0.47 |

As demonstrated in Examples, the optical constants could be changed by changing the types of compounds that were combined.

(Measurement of Dry Etching Rate)

The etcher and etching gas used for the measurement of dry etching rate were as follows:

RIE-200NR (manufactured by Samco) and CF₄

Each of the solutions of a resist underlayer film-forming composition prepared in Comparative Example 1 and Examples 1 to 12 was applied onto a silicon wafer using a spin coater. The applied film was baked on a hot plate at 240° C., 350° C., or 400° C. for 60 seconds to form a resist underlayer film (film thickness: 200 nm). The dry etching rate was measured using CF₄ gas as the etching gas. The dry etching rate of Comparative Example 1 and Examples 1 to 12 was expressed as dry etching rate ratio of (resist underlayer film)/(KrF photoresist) (Table 3).

TABLE 3
Etching rate ratio

| | | Etching rate ratio |
|---|---|---|
| Comparative Example 1 | 350° C.-Baked film | 0.96 |
| Example 1 | 240° C.-Baked film | 1.05 |
| Example 1 | 350° C.-Baked film | 1.06 |
| Example 2 | 240° C.-Baked film | 1.00 |
| Example 2 | 350° C.-Baked film | 1.03 |
| Example 3 | 240° C.-Baked film | 1.09 |
| Example 3 | 350° C.-Baked film | 1.06 |
| Example 3 | 400° C.-Baked film | 1.09 |
| Example 4 | 240° C.-Baked film | 1.07 |
| Example 5 | 240° C.-Baked film | 0.93 |
| Example 6 | 240° C.-Baked film | 1.02 |
| Example 7 | 240° C.-Baked film | 1.08 |
| Example 8 | 240° C.-Baked film | 1.00 |
| Example 9 | 240° C.-Baked film | 1.03 |
| Example 10 | 240° C.-Baked film | 1.03 |
| Example 11 | 240° C.-Baked film | 1.01 |
| Example 12 | 240° C.-Baked film | 1.05 |

As demonstrated in Examples, the etching rate could be changed by changing the types of compounds that were combined.

(Measurement of Amount of Sublimates)

The amount of sublimates was measured using the sublimate measuring apparatus according to WO 2007/111147. Each of the resist underlayer film-forming compositions prepared in Comparative Example 1 and Examples 1 to 12 was applied to a silicon wafer, and the applied film was baked at 240° C., 350° C., or 400° C. for 60 seconds to form a 200 nm thick film. The amount of sublimates generated during this process was measured (Table 4). The values according to the table are the ratio of the amount of sublimates in each of Examples 1 to 12 to the amount of sublimates in Comparative Example 1.

TABLE 4
Measurement of amount of sublimates

| | | Amount of sublimates |
|---|---|---|
| Comparative Example 1 | 350° C.-Baked film | 1.00 |
| Example 1 | 240° C.-Baked film | 0.19 |
| Example 1 | 350° C.-Baked film | 0.23 |
| Example 2 | 240° C.-Baked film | 0.12 |
| Example 2 | 350° C.-Baked film | 0.16 |
| Example 3 | 240° C.-Baked film | 0.16 |
| Example 3 | 350° C.-Baked film | 0.33 |
| Example 3 | 400° C.-Baked film | — |
| Example 4 | 240° C.-Baked film | 0.15 |
| Example 5 | 240° C.-Baked film | 0.14 |
| Example 6 | 240° C.-Baked film | 0.13 |
| Example 7 | 240° C.-Baked film | 0.20 |
| Example 8 | 240° C.-Baked film | 0.20 |
| Example 9 | 240° C.-Baked film | 0.20 |
| Example 10 | 240° C.-Baked film | 0.21 |
| Example 11 | 240° C.-Baked film | 0.12 |
| Example 12 | 240° C.-Baked film | 0.28 |

### Amount of Sublimates

*In Table 4, the measurement was infeasible at 400° C. for device reasons.

From the comparison between Comparative Example 1 and Examples 1 to 12, introduction of specific crosslinking groups into the polymer brought about a significant reduction in the amount of sublimates in all of the cases, where a crosslinking agent and an acid catalyst were used, only an acid catalyst was used, and neither a crosslinking agent nor an acid catalyst was used. Moreover, the amount of sublimates could also be reduced even when the compound that was reacted was changed. Thus, it would be possible to lower the risk of device contamination.

(Measurement of Hardness)

Each of the resist underlayer film-forming compositions prepared in Comparative Example 1 and Examples 1 to 12 was applied to the substrate described hereinabove, and the applied film was baked at 240° C., 350° C., or 400° C. for 60 seconds to form a 200 nm resist underlayer film. The hardness of the resist cured films was evaluated with TI-980 Triboidentor manufactured by Bruker. Based on Comparative Example 1 as the reference, the hardness higher than that of Comparative Example 1 was rated as ∘ (Table 5).

TABLE 5
Measurement of hardness

| | | Hardness |
|---|---|---|
| Comparative Example 1 | 350° C.-Baked film | Reference |
| Example 1 | 240° C.-Baked film | ◯ |
| Example 1 | 350° C.-Baked film | ◯ |
| Example 2 | 240° C.-Baked film | ◯ |
| Example 2 | 350° C.-Baked film | ◯ |
| Example 3 | 240° C.-Baked film | ◯ |
| Example 3 | 350° C.-Baked film | ◯ |
| Example 3 | 400° C.-Baked film | ◯ |
| Example 4 | 240° C.-Baked film | ◯ |
| Example 5 | 240° C.-Baked film | ◯ |
| Example 6 | 240° C.-Baked film | ◯ |
| Example 7 | 240° C.-Baked film | ◯ |
| Example 8 | 240° C.-Baked film | ◯ |
| Example 9 | 240° C.-Baked film | ◯ |
| Example 10 | 240° C.-Baked film | ◯ |
| Example 11 | 240° C.-Baked film | ◯ |
| Example 12 | 240° C.-Baked film | ◯ |

From the comparison between Comparative Example 1 and Examples 1 to 12, introduction of specific crosslinking groups into the polymer brought about an increased hardness in all of the cases, where a crosslinking agent and an acid catalyst were used, only an acid catalyst was used, and neither a crosslinking agent nor an acid catalyst was used. Hardness is usually increased with increasing baking temperature. However, low-temperature baking at 240° C. in Examples resulted in a higher hardness than Comparative Example in which baking was performed at a high temperature of 350° C. Thus, good bend resistance will be obtained not only when baking is performed at a high temperature, but also when the baking temperature is low.

(Evaluation of Gap-Filling Property)

Gap-filling property was evaluated using a 200 nm thick SiO₂ substrate that had a dense pattern area consisting of 50 nm wide trenches at 100 nm pitches. Each of the resist underlayer film-forming compositions prepared in Comparative Example 1 and Examples 1 to 12 was applied onto the substrate, and the applied film was baked at 240° C., 350° C., or 400° C. for 60 seconds to form a resist underlayer film having a thickness of about 200 nm. The flatness of the substrates was evaluated using a scanning electron microscope (S-4800) manufactured by Hitachi High-Tech Corporation, and whether the resist underlayer film-forming composition had filled the inside of the pattern was determined (Table 6).

The gap-filling property was rated as ∘ when the resist underlayer film-forming composition had filled the inside of the pattern, and as x when the resist underlayer film-forming composition had failed to fill the inside of the pattern.

TABLE 6
Evaluation of gap-filling property

| | | Gap-filling property |
|---|---|---|
| Comparative Example 1 | 350° C.-Baked film | ◯ |
| Example 1 | 240° C.-Baked film | ◯ |
| Example 1 | 350° C.-Baked film | ◯ |
| Example 2 | 240° C.-Baked film | ◯ |
| Example 2 | 350° C.-Baked film | ◯ |
| Example 3 | 240° C.-Baked film | ◯ |
| Example 3 | 350° C.-Baked film | ◯ |
| Example 3 | 400° C.-Baked film | ◯ |
| Example 4 | 240° C.-Baked film | ◯ |
| Example 5 | 240° C.-Baked film | ◯ |
| Example 6 | 240° C.-Baked film | ◯ |
| Example 7 | 240° C.-Baked film | ◯ |
| Example 8 | 240° C.-Baked film | ◯ |
| Example 9 | 240° C.-Baked film | ◯ |
| Example 10 | 240° C.-Baked film | ◯ |
| Example 11 | 240° C.-Baked film | ◯ |
| Example 12 | 240° C.-Baked film | ◯ |

Examples attained a high gap-filling property similarly to the conventional material (=Comparative Example).

(Evaluation of Bend Resistance)

Each of the solutions of a resist underlayer film-forming composition prepared in Comparative Example 1 and Example 12 was applied onto a silicon oxide-coated silicon wafer using a spin coater. The applied film was baked on a hot plate at 350° C. for 60 seconds to form a resist underlayer film (film thickness: 200 nm). A silicon hard mask-forming composition solution was applied onto the resist underlayer film, and the applied film was baked at 240° C. for 1 minute to form a silicon hard mask layer (film thickness: 30 nm). A resist solution was applied thereto, and the applied film was baked at 100° C. for 1 minute to form a resist layer (film thickness: 150 nm). The resist layer was exposed to 193 nm wavelength light through a mask. Post exposure baking, PEB, was performed (at 105° C. for 1 minute), and the latent image was developed to form a resist pattern. Subsequently, dry etching was performed using a fluorine-containing gas and an oxygen-containing gas to transfer the resist pattern to the silicon oxide-coated silicon wafer. The shapes of the respective patterns were observed with CG-4100 manufactured by Hitachi High-Tech Corporation.

A pattern tends to bend irregularly as the pattern width decreases. The presence of such irregular bending disenables faithful processing of a substrate. Thus, a higher bend resistance allows for finer substrate processing (Table 7). The bend resistance higher than that of Comparative Example was rated as ∘.

TABLE 7
Evaluation of bend resistance

| | | Bend resistance test |
|---|---|---|
| Comparative Example 1 | 350° C.-Baked film | Reference |
| Example 1 | 350° C.-Baked film | ◯ |
| Example 2 | 350° C.-Baked film | ◯ |
| Example 3 | 350° C.-Baked film | ◯ |
| Example 4 | 350° C.-Baked film | ◯ |
| Example 5 | 350° C.-Baked film | ◯ |
| Example 6 | 350° C.-Baked film | ◯ |
| Example 7 | 350° C.-Baked film | ◯ |
| Example 8 | 350° C.-Baked film | ◯ |
| Example 9 | 350° C.-Baked film | ◯ |
| Example 10 | 350° C.-Baked film | ◯ |
| Example 11 | 350° C.-Baked film | ◯ |
| Example 12 | 350° C.-Baked film | ◯ |

Next, the performance of the material of the present invention as a crosslinking agent was evaluated as follows. The dissolution into a resist solvent was tested, the optical constants were measured, the dry etching rate was measured, and the hardness and the bend resistance were tested by the methods described hereinabove. Moreover, the covering performance on stepped substrates was tested, and the heat resistance was evaluated as follows.

(Test of Covering Performance on Stepped Substrates)

To test the covering performance on a stepped substrate, the film thickness was compared between at an open area (OPEN) of the substrate free from patterns and at a dense pattern area (DENSE) of the substrate consisting of 50 nm wide trenches at 100 nm pitches. Each of the resist underlayer film-forming compositions prepared in Comparative Example 2 and Example 13 was applied to a 200 nm thick SiO₂ substrate, and the applied film was baked at 350° C. for 60 seconds to form a resist underlayer film having a thickness of about 200 nm. The flatness of the substrates was evaluated using a scanning electron microscope (S-4800) manufactured by Hitachi High-Tech Corporation by measuring the difference in film thickness between on the trenched area (the patterned area) and on the open area (the pattern-free area) of the stepped substrate (the step height created on the coating film between the trenched area and the open area, called the bias). Here, the flatness means how small the difference is in the film thickness (the iso-dense bias) of the coating film between on the region with the pattern (the trenched area (the patterned area)) and on the region without patterns (the open area (the pattern-free area)). The flatness was rated as ∘ when the bias was smaller than in Comparative Example 2.

(Evaluation of Heat Resistance)

Each of the solutions of a resist underlayer film-forming composition prepared in Comparative Example 2 and Example 13 was applied onto a silicon wafer using a spin coater, and the applied film was baked on a hot plate at 350° C. for 60 seconds to form a 200 nm resist underlayer film. Pieces scraped from the films obtained were heated, while increasing the temperature from room temperature (about 20° C.) at a rate of 10° C. per minute. The change in weight loss with the passage of time was determined by thermogravimetric analysis in the air.

The heat resistance was rated as ∘ when the weight loss ratio was lower than in Comparative Example 2.

TABLE 8
Evaluation of characteristics

| | | | Optical | | | | | |
|---|---|---|---|---|---|---|---|---|
| | Baking | Dissolution | constants | Etching | | Heat | | Bend |
| Sample | temperature | test | @193 nm | rate ratio | Flatness | resistance | Hardness | resistance |
| Comparative | 350° C. | ◯ | 1.40/0.47 | 0.83 | X | Reference | Reference | Reference |
| Example. 2 | 60 sec. | | | | | | | |
| Ex. 13 | 350° C. | ◯ | 1.42/0.49 | 0.82 | ◯ | ◯ | ◯ | ◯ |
| | 60 sec. | | | | | | | |

From the above, use of the material of the present invention as a crosslinking agent made it possible to impart a higher flatness, higher heat resistance, higher hardness, and higher bend resistance than did the comparative crosslinking agent of Comparative Example.

### Industrial Applicability

The novel resist underlayer film-forming composition provided according to the present invention meets demands, specifically, is self-cured at a low temperature even without containing an acid catalyst or a crosslinking agent, generates reduced amounts of sublimates, and can form high-hardness films exhibiting high bend resistance. The resist underlayer film-forming composition is also usable as a crosslinking agent. When used as a crosslinking agent, the composition offers higher levels of flatness and heat resistance than the conventional crosslinking agents. Moreover, the composition compares equally to the conventional products in gap-filling property, and enables free control of optical constants and etching resistance through the selection of monomers.

1. A resist underlayer film-forming composition comprising:
a solvent, and
a polymer (X) comprising a repeating structural unit, in which an aromatic compound A having an ROCH₂— group (R is a monovalent organic group, a hydrogen atom, or a mixture thereof) and a C₁₂₀ or lower aromatic compound B different from the compound A are alternately bonded to each other via a linking group —O—, the repeating structural unit being such that 1 to 6 molecules of the compound B are bonded to one molecule of the compound A.

2. The resist underlayer film-forming composition according to claim 1, wherein the polymer (X) comprises a repeating structural unit represented by the formula (1):
[Chem. 36]
A₁-O—B₁—O Formula (1)
(in the formula (1), A₁ denotes an organic group derived from the aromatic compound A having an ROCH₂— group (R is a monovalent organic group, a hydrogen atom, or a mixture thereof) and B₁ denotes an organic group different from A₁ and derived from the C₁₂₀ or lower aromatic compound B).

3. The resist underlayer film-forming composition according to claim 2, wherein R in the formula (1) is a saturated or unsaturated, linear or branched, and C₂-C₂₀ aliphatic or C₃-C₂₀ alicyclic hydrocarbon group optionally substituted with a phenyl group, a naphthyl group, or an anthracenyl group and optionally interrupted by an oxygen atom, a nitrogen atom, or a carbonyl group; a hydrogen atom; or a mixture thereof.

4. The resist underlayer film-forming composition according to claim 2, wherein B₁ in the formula (1) is represented by the following formula 2: 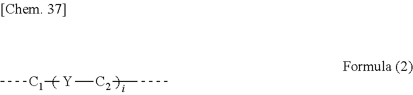
(in the formula (2),
C₁ and C₂ each independently denote a C₆-C₄₈ aromatic ring having 6 to 48 carbon atoms and optionally containing a heteroatom, or a hydrocarbon group containing a C₆-C₄₈ aromatic ring optionally containing a heteroatom,
Y denotes a single bond, a carbonyl group, a sulfonyl group, a —CR¹₂— group, or a —(CF₃)C(CF₃)— group,
R¹ denotes a C₁-C₁₀ alkyl group optionally interrupted by an oxygen atom, a carbonyl group, a nitrogen atom, a carbon-carbon double bond, or a carbon-carbon triple bond, and optionally having a carbon-carbon double bond or a carbon-carbon triple bond at a terminal; a hydroxy group; a hydrogen atom; a halogen; a C₆-C₂₀ aromatic hydrocarbon group; or —NR²₂,
R² denotes a C₁-C₁₀ chain or cyclic alkyl group,
i is 0 or 1, and
the dotted line denotes a bond with the oxygen atom).

5. The resist underlayer film-forming composition according to claim 4, wherein i in the formula (2) is 1.

6. The resist underlayer film-forming composition according to claim 4, wherein the polymer (X) further comprises a repeating structural unit represented by the formula (3):
[Chem. 38]
A₂-O—B₁—O Formula (3)
(in the formula (3), B₁ is represented by the formula 2, and A₂ denotes an organic group different from B₁ and derived from a 0120 or lower aromatic compound A′).

7. The resist underlayer film-forming composition according to claim 2, wherein A₁ in the formula (1) has no phenolic hydroxy group.

8. The resist underlayer film-forming composition according to claim 1, wherein the polymer (X) has an optionally substituted C₆-C₃₀ aromatic hydrocarbon group at least one end thereof.

9. The resist underlayer film-forming composition according to claim 1, further comprising a film material (Z) capable of undergoing a crosslinking reaction with the polymer (X).

10. The resist underlayer film-forming composition according to claim 1, further comprising a crosslinking agent.

11. The resist underlayer film-forming composition according to claim 1, further comprising an acid and/or an acid generator.

12. The resist underlayer film-forming composition according to claim 1, further comprising a surfactant.

13. The resist underlayer film-forming composition according to claim 1, wherein the solvent comprises a solvent having a boiling point of 160° C. or above.

14. A resist underlayer film, which is a baked product of a coating film of the composition according to claim 1.

15. A process for manufacturing a semiconductor device, comprising the steps of:
forming a resist underlayer film using the composition according to claim 1 on a semiconductor substrate;
forming a resist film on the resist underlayer film;
forming a resist pattern by applying a light or electron beam to the resist film followed by development;
forming a pattern in the resist underlayer film by etching the resist underlayer film through the formed resist pattern; and
processing the semiconductor substrate through the pattern in the resist underlayer film.

16. A process for manufacturing a semiconductor device, comprising the steps of:
forming a resist underlayer film using the composition according to claim 1 on a semiconductor substrate;
forming a hard mask on the resist underlayer film;
forming a resist film on the hard mask;
applying a light or electron beam to the resist film followed by development to form a resist pattern;
etching the hard mask through the formed resist pattern to form a patterned hard mask; and
etching the resist underlayer film through the patterned hard mask to form a patterned resist underlayer film; and
processing the semiconductor substrate through the patterned resist underlayer film.

17. The process for manufacturing a semiconductor device according to claim 15, wherein the step of forming a resist underlayer film is performed by a nanoimprinting method.
